(19) United States
(12) Patent Application Publication
(10) Pub. No.: US 2024/0201602 A1
(43) Pub. Date: Jun. 20, 2024

(54) SUBSTRATE PROCESSING APPARATUS

(71) Applicants: ACM RESEARCH (SHANGHAI), INC., Shanghai (CN); ACM Research Korea CO., LTD., Icheon-si (KR); CleanChip Technologies Limited, Hong Kong (CN)

(72) Inventors: Hui Wang, Shanghai (CN); Mark Lee, Icheon-si (KR); Jun Wu, Shanghai (CN); Cheng Cheng, Shanghai (CN); Andrew Jung, Icheon-si (KR); Bruce Sohn, Icheon-si (KR); Jun Wang, Shanghai (CN); Yy Kim, Icheon-si (KR)

(73) Assignees: ACM RESEARCH (SHANGHAI), INC., Shanghai (CN); ACM Research Korea CO., LTD., Gyeong-Gi-Do (KR); CleanChip Technologies Limited, Hong Kong (CN)

(21) Appl. No.: 18/557,226

(22) PCT Filed: Apr. 25, 2021
(86) PCT No.: PCT/CN2021/089596

§ 371 Date: Oct. 25, 2023

(51) Int. Cl. G03F 7/00; G03F 7/16

(52) U.S. Cl. CPC G03F 7/7075; G03F 7/168; G03F 7/70533; G03F 7/70825; G03F 7/70933

(57) ABSTRACT

Embodiments of the present invention provide a substrate processing apparatus comprising a chemical liquid processing apparatus. The chemical liquid processing apparatus includes a first chemical liquid processing part, a second chemical liquid processing part configured to be stacked with the first chemical liquid processing part, a heating processing part located opposite the first chemical liquid processing part and the second chemical liquid processing part and a substrate transferring part located between the first and second chemical liquid processing parts and the heating processing part. The substrate transferring part is configured to have at least two first robots, at least one second robot and at least one third robot, all of which are arranged in parallel layers, and at least one pair of first buffer units located between two adjacent first robots and configured for loading and unloading the substrates therein and therefrom via the at least one second robot. The at least two first robots are configured to transfer the substrates between the first chemical liquid processing part and the heating processing part and the at least one third robot is configured to transfer the substrates between the second chemical liquid processing part and the heating processing part.

### BACKGROUND OF THE INVENTION

### 1. Field of the Invention

Various embodiments may generally relate to a substrate processing apparatus, and more particularly to an inline chemical liquid processing apparatus capable of performing coating processing and developing processing of chemical liquids on a substrate, and a substrate processing apparatus including the same.

### 2. The Related Art

In general, a method of forming a photoresist pattern on a substrate, for example, a semiconductor wafer may be performed using a coating process of forming a photoresist film by coating a photoresist liquid on the substrate through a coating apparatus, an exposure process of irradiating light having a predetermined pattern into the photoresist film through an exposure apparatus, a developing process of forming the photoresist pattern by applying a developing liquid to the photoresist film through a developing apparatus, and the like.

An inline chemical liquid processing apparatus in which an exposure apparatus is coupled to a coating apparatus and a developing apparatus has been increasingly used and a heating apparatus, which performs a heat treatment process on a substrate before and after a photoresist liquid and a developing liquid are applied to the substrate, is provided in the chemical liquid processing apparatus.

In recent years, a chemical liquid processing apparatus capable of performing coating and developing of chemical liquids needs to have performance for processing lots of substrates once, and thus the numbers of heating modules, coating modules and developing modules, which are installed in one chemical liquid processing apparatus, have been increased. To reduce an area occupied by the coating modules and the developing modules constituting the chemical liquid processing apparatus, the modules are installed in such a manner that the coating modules and the developing modules are vertically stacked.

For performing the coating process and the developing process of substrates, the chemical liquid processing apparatus further has a plurality of process robots to transfer the substrates among the heating modules, the coating modules and the developing modules. At present, in order to improve the throughput of the chemical liquid processing apparatus, existing manufacturers only increase the numbers of heating modules, coating modules and developing modules as well as the number of stacked layers in the chemical liquid processing apparatus, which causes the process robots are too busy, and at last, the throughput is not significantly increased. The throughput is limited by the transfer efficiency of the process robots. If simply increase the numbers of heating modules, coating modules and developing modules as well as the number of stacked layers without optimizing other structures of the chemical liquid processing apparatus, it will be difficult to increase the throughput.

### SUMMARY

Embodiments are provided to a substrate processing apparatus capable of providing expandability options so as to increase productivity.

Embodiments are provided to a substrate processing apparatus capable of improving substrate transfer efficiency so as to improve throughput.

In an embodiment of the present disclosure, a substrate processing apparatus comprises a chemical liquid processing apparatus configured to perform processing on substrates. The chemical liquid processing apparatus includes a first chemical liquid processing part configured to supply a first chemical liquid to the substrates and perform first chemical processing on the substrates, a second chemical liquid processing part configured to be stacked with the first chemical liquid processing part and to supply a second chemical liquid to the substrates and perform second chemical processing on the substrates, a heating processing part located opposite the first chemical liquid processing part and the second chemical liquid processing part and configured to perform a heating treatment operation on the substrates before and after the first chemical processing on the substrates or the second chemical processing on the substrates and a substrate transferring part located between the first and second chemical liquid processing parts and the heating processing part. The substrate transferring part is configured to have at least two first robots, at least one second robot and at least one third robot, all of which are arranged in parallel layers, and at least one pair of first buffer units located between two adjacent first robots and configured for loading and unloading the substrates therein and therefrom via the at least one second robot. The at least two first robots are configured to transfer the substrates between the first chemical liquid processing part and the heating processing part and the at least one third robot is configured to transfer the substrates between the second chemical liquid processing part and the heating processing part.

Embodiments are provided to a chemical liquid processing apparatus capable of automatically adjusting at least one nozzle to align with a center of a substrate positioned in a processing unit.

In an embodiment of the present disclosure, a chemical liquid processing apparatus comprises at least one nozzle apparatus, at least one processing unit and a controller. The nozzle apparatus comprises a supporting arm; a driving actuator configured to be positioned on the supporting arm; a nozzle holder configured to be connected to the driving actuator and be driven to move by the driving actuator; at least one nozzle configured to be fixed with the nozzle holder; a supporting shaft configured to be fixed with the supporting arm; a vertical driving device configured to be connected to the supporting shaft to drive the supporting shaft to move upwards or downwards; a rotating driving device configured to be connected to the supporting shaft to drive the supporting shaft to rotate; and the controller is configured to be respectively connected to the driving actuator, the vertical driving device and the rotating driving device.

In an embodiment of the present disclosure, a method for adjusting at least one nozzle to align with a center of a substrate positioned in a processing unit, comprising: establishing polar coordinates in a controller, wherein the controller is connected to a rotating driving device configured to drive the at least one nozzle to rotate, a vertical driving device configured to drive the at least one nozzle to move upwards or downwards and a driving actuator configured to drive the at least one nozzle to move forwards or backwards; obtaining a polar point of the at least one nozzle and recording the polar point of the at least one nozzle in the controller, wherein the polar point of the at least one nozzle aligns the center of the substrate in the processing unit; the controller sending instructs to the rotating driving device and the driving actuator based on the polar point of the at least one nozzle recorded in the controller to make the at least one nozzle reach the polar point so that the at least one nozzle aligns with the center of the substrate in the processing unit.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a perspective view illustrating a substrate processing apparatus according to an embodiment of the present disclosure;

FIG. 2 is a front perspective view illustrating a substrate processing apparatus according to an embodiment of the present disclosure;

FIG. 3 is a rear perspective view illustrating a substrate processing apparatus according to an embodiment of the present disclosure;

FIG. 4 is a top view illustrating developing modules in a substrate processing apparatus according to an embodiment of the present disclosure;

FIG. 5 is a top view illustrating coating modules in a substrate processing apparatus according to an embodiment of the present disclosure;

FIG. 6 is a perspective view illustrating a process block in a substrate processing apparatus according to an embodiment of the present disclosure;

FIG. 7 is a perspective view illustrating a process block hiding developing modules and coating modules according to an embodiment of the present disclosure;

FIG. 8 is a perspective view illustrating a process block hiding heating modules according to an embodiment of the present disclosure;

FIG. 9 is a perspective view illustrating a process block hiding heating modules according to another embodiment of the present disclosure;

FIG. 10 is a perspective view illustrating a process block hiding heating modules according to yet another embodiment of the present disclosure;

FIG. 11 is a perspective view illustrating a process block hiding heating modules according to another embodiment of the present disclosure;

FIG. 12 is a perspective view illustrating a substrate processing apparatus according to another embodiment of the present disclosure;

FIG. 13 is a front perspective view illustrating a substrate processing apparatus according to another embodiment of the present disclosure;

FIG. 14 is a rear perspective view illustrating a substrate processing apparatus according to another embodiment of the present disclosure;

FIG. 15 is a top view illustrating developing modules in a substrate processing apparatus according to another embodiment of the present disclosure;

FIG. 16 is a top view illustrating coating modules in a substrate processing apparatus according to another embodiment of the present disclosure;

FIG. 17 is a perspective view illustrating a process block in a substrate processing apparatus according to another embodiment of the present disclosure;

FIG. 18 is a perspective view illustrating a process block hiding developing modules and coating modules according to another embodiment of the present disclosure;

FIG. 19 is a perspective view illustrating a process block hiding heating modules according to another embodiment of the present disclosure;

FIG. 20 is a perspective view illustrating a process block hiding developing modules and coating modules according to yet another embodiment of the present disclosure;

FIG. 21 is a perspective view illustrating a process block hiding developing modules and coating modules according to yet another embodiment of the present disclosure;

FIG. 22 is a perspective view illustrating a substrate processing apparatus according to yet another embodiment of the present disclosure;

FIG. 23 is a diagram illustrating an operation of controlling a temperature of a substrate in a heating module according to an embodiment of the present disclosure;

FIG. 24 is a perspective view illustrating a coating module in a chemical liquid processing apparatus according to an embodiment of the present disclosure;

FIG. 25 is a top view illustrating a coating module in a chemical liquid processing apparatus according to another embodiment of the present disclosure;

FIG. 26 is a block diagram illustrating a control of a coating nozzle or a developing nozzle aligning with a center of a substrate in a coating unit or a developing unit in a chemical liquid processing apparatus according to an embodiment of the present disclosure;

FIG. 27 is a diagram illustrating an exemplary method for aligning a coating nozzle or a developing nozzle with a center of a substrate in a coating unit or a developing unit in a chemical liquid processing apparatus according to an embodiment of the present disclosure;

FIG. 28 is a perspective view illustrating a developing module in a chemical liquid processing apparatus according to an embodiment of the present disclosure;

FIG. 29 is a perspective view illustrating a coating module in a chemical liquid processing apparatus according to another embodiment of the present disclosure;

FIG. 30 is a perspective view illustrating a coating module hiding a plurality of chemical liquid nozzles according to another embodiment of the present disclosure; and

FIG. 31 is a perspective view illustrating a chemical liquid nozzle of a coating module being fetched and rotated to a center of a substrate positioned in a coating unit according to an embodiment of the present disclosure.

### DETAILED DESCRIPTION OF EMBODIMENTS

Hereinafter, exemplary embodiments of the present disclosure will be described more fully with reference to the accompanying drawings, in which the exemplary embodiments of the present disclosure are shown to understand a configuration and an effect of the present disclosure. However, specific structural and functional details disclosed herein are merely representative for purposes of describing exemplary embodiments. Thus, the invention may be embodied in many alternate forms and should not be construed as limited to only exemplary embodiments set forth herein. Exemplary embodiments are to cover all modifications, equivalents, and alternatives falling within the scope of the inventive concept.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Spatially relative terms, such as “beneath,” “below,” “lower,” “above,” “upper” and the like, may be used herein for ease of description to describe one element or a relationship between a feature and another element or feature as illustrated in the figures. For example, if the apparatus in the figures is turned over, elements described as “below” or “beneath” other elements or features would then be oriented “above” the other elements or features. Thus, for example, the term “below” can encompass both an orientation which is above as well as below. The apparatus may be otherwise oriented (rotated 90 degrees or viewed or referenced at other orientations) and the spatially relative descriptors used herein should be interpreted accordingly.

The terminology used herein is for the purpose of describing particular embodiments only and is not intended to be limiting of the present inventive concept. As used herein, the singular forms “a.” “an” and “the” are intended to include the plural forms as well, unless the context clearly indicates otherwise. It will be further understood that the terms “comprises” and/or “comprising,” when used in this specification, specify the presence of stated features, integers, steps, operations, elements, components, and/or groups thereof, but do not preclude the presence or addition of one or more other features, integers, steps, operations, elements, components, and/or groups thereof.

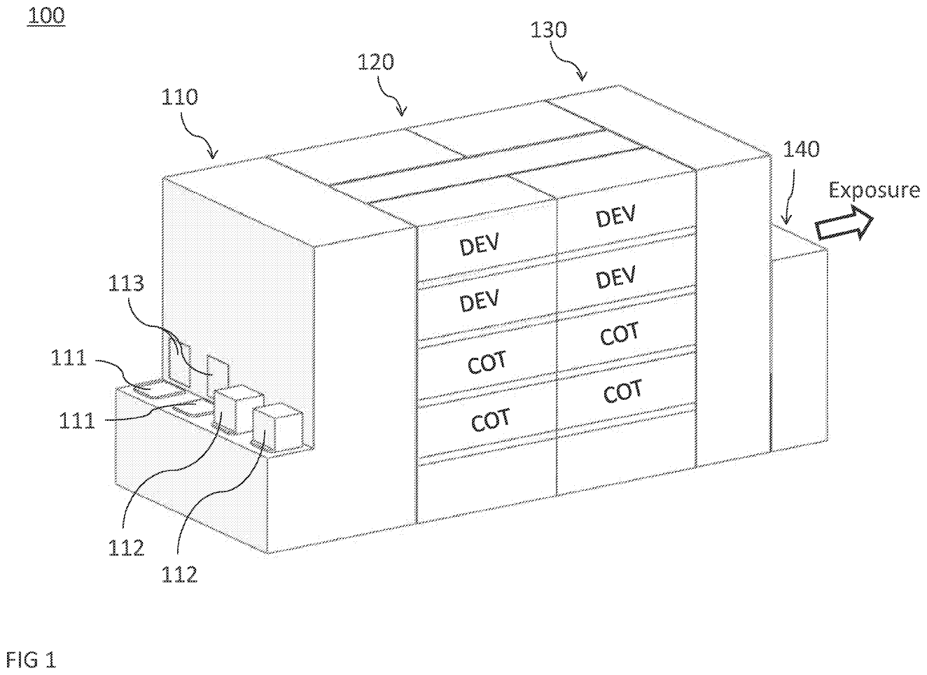

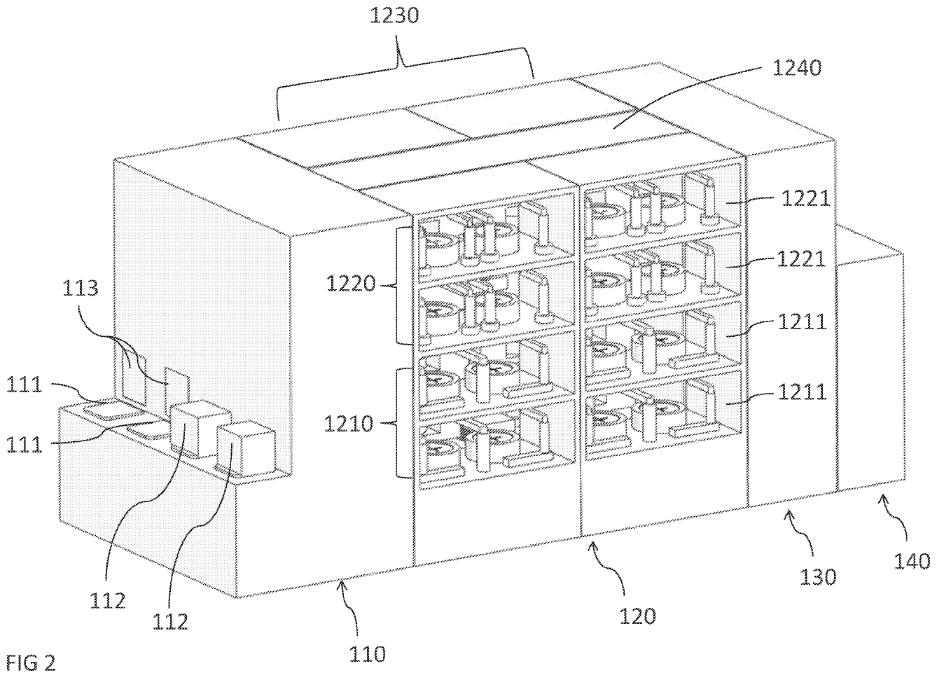

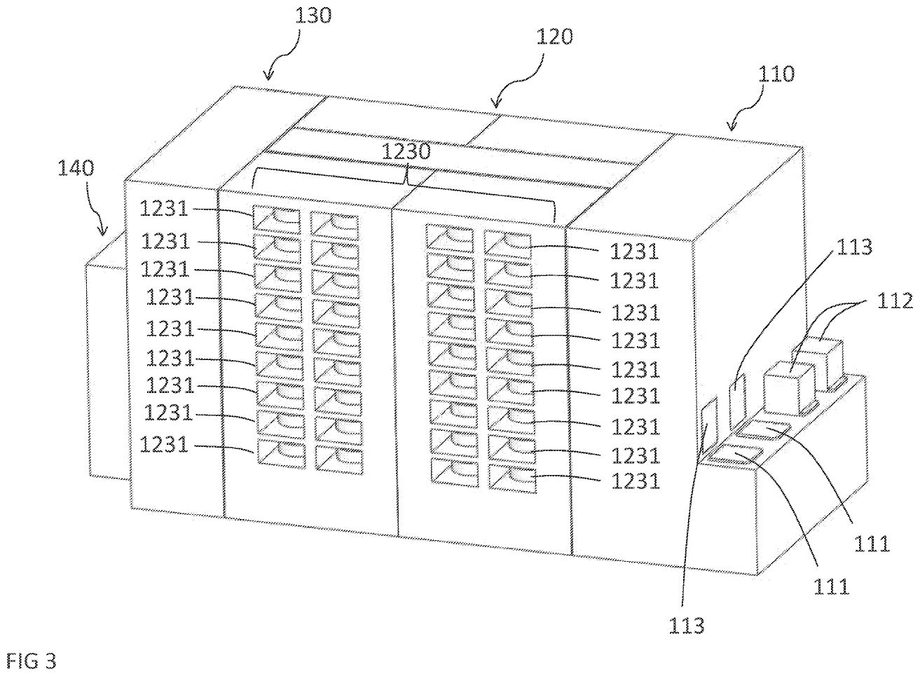

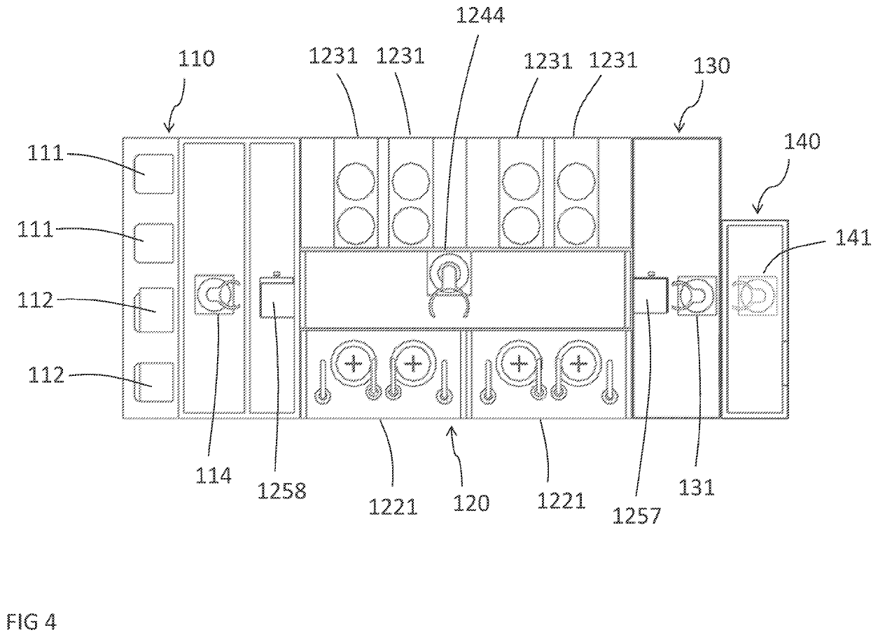

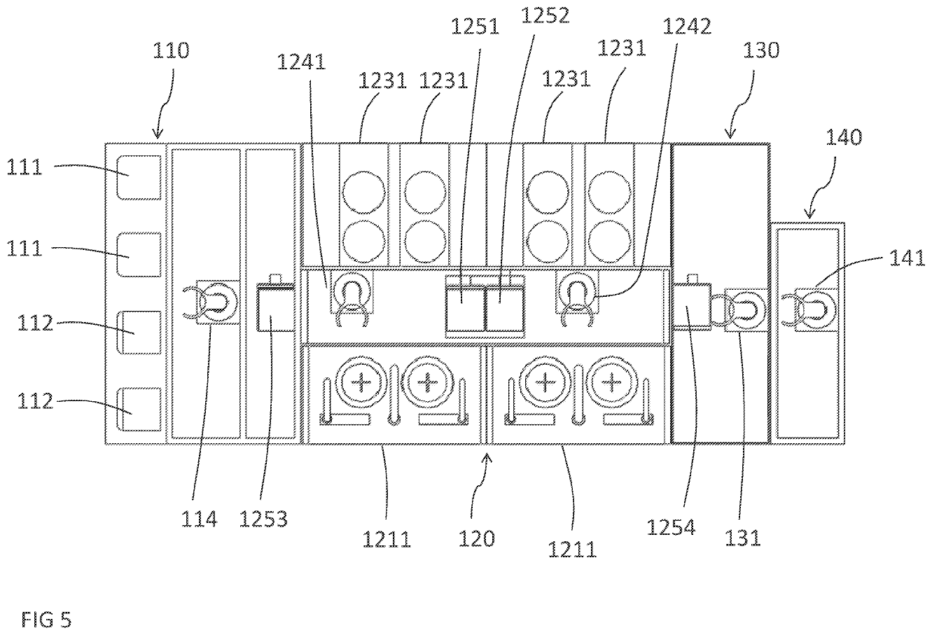

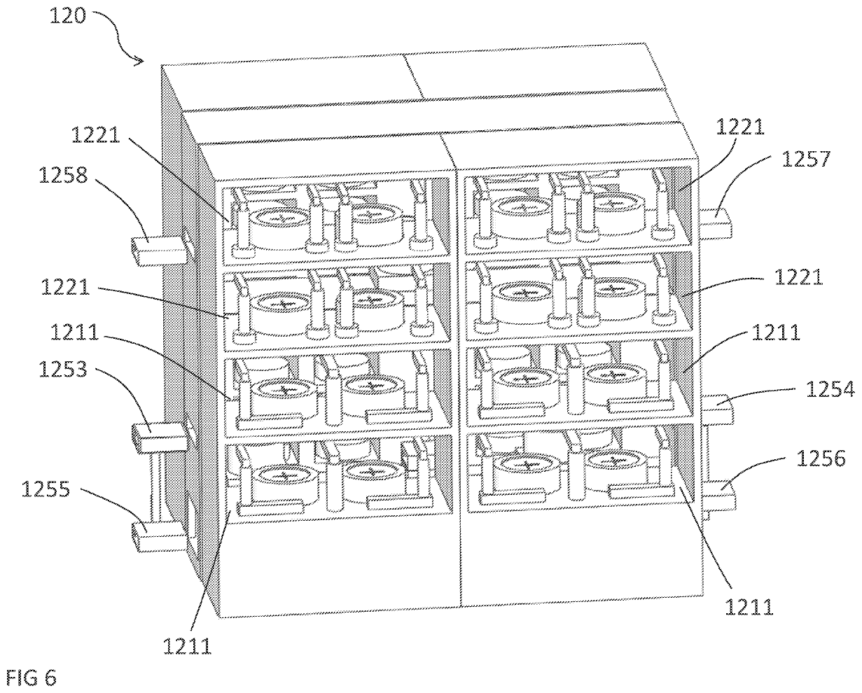

Referring to FIG. 1 to FIG. 8, a substrate processing apparatus according to an exemplary embodiment of the present disclosure is illustrated. The substrate processing apparatus 100 includes a first carrying block 110, a process block 120, a second carrying block 130 and an interface block 140.

The first carrying block 110 is configured to load and unload substrates into and from the process block 120 through a first carrying unit 114 disposed in the first carrying block 110. The first carrying block 110 has a plurality of cassette loading parts 111, in which cassettes 112 that a fixed number of substrates (for example, twenty five pieces of wafers) are sealed and stored are placed. A plurality of opening/closing parts 113 are arranged in the front of the first carrying block 110 and corresponding to the cassette loading parts 111 along a transfer direction of a substrate, and the substrates accommodated in the cassette 112 may be transferred into the first carrying block 110 through the opening/closing part 113.

The process block 120 is disposed at one side of the first carrying block 110 and configured to perform a chemical liquid processing process, a heating process, and the like, and a chemical liquid processing apparatus to be described later is disposed in the process block 120. The second carrying block 130 which couples the process block 120 and the interface block 140 is disposed at one side of the process block 120 and the interface block 140 configured to perform an inline work with an external apparatus such as exposure apparatus (not shown) is disposed at one side of the second carrying block 130. The second carrying block 130 is configured to carry substrates coating-processed in the process block 120 to the interface block 140 and carry substrates exposure-processed in the exposure apparatus to the process block 120 through a second carrying unit 131. The interface block 140 is configured to carry substrates exposure-processed in the exposure apparatus to the process block 120 and carry substrates coating-processed in the process block 120 to the exposure apparatus through a third carrying unit 141.

The example that the substrate processing apparatus 100 is divided into four blocks has been illustrated, but this is not limited thereto. Any apparatus, in which the process block 120 that the chemical liquid processing apparatus configured to perform coating and developing processes is located, is coupled to the exposure apparatus in an inline form, may be applied.

The process block 120 according to an embodiment of the present disclosure includes a chemical liquid processing apparatus configured to perform chemical liquid processing and heating processing on the substrates. The chemical liquid processing apparatus includes a first chemical liquid processing part 1210, a second chemical liquid processing part 1220, a heating processing part 1230 and a substrate transferring part 1240. The first chemical liquid processing part 1210 is configured to supply a first chemical liquid to the substrates and perform first chemical processing on the substrates. The second chemical liquid processing part 1220 is stacked with the first chemical liquid processing part 1210 and configured to supply a second chemical liquid to the substrates and perform second chemical processing on the substrates. The heating processing part 1230 is located opposite the first chemical liquid processing part 1210 and the second chemical liquid processing part 1220 and configured to perform a heating treatment operation on the substrates before and after the first chemical processing on the substrates or the second chemical processing on the substrates. The substrate transferring part 1240 is located between the first and second chemical liquid processing parts 1210, 1220 and the heating processing part 1230. The substrate transferring part 1240 is configured to have at least two first robots 1241, 1242, at least one second robot 1243, at least one third robot 1244 and at least one pair of first buffer units 1251, 1252. The at least two first robots 1241, 1242, the at least one second robot 1243 and the at least one third robot 1244 are arranged in parallel layers. The at least two first robots 1241, 1242 are configured to transfer the substrates between the first chemical liquid processing part 1210 and the heating processing part 1230. The at least one third robot 1244 is configured to transfer the substrates between the second chemical liquid processing part 1220 and the heating processing part 1230. The at least one pair of first buffer units 1251, 1252 is located between the two adjacent first robots 1241, 1242 and configured for loading and unloading the substrates therein and therefrom via the at least one second robot 1243.

According to an embodiment of the present disclosure, the first chemical liquid processing part 1210 is disposed in a lower side of the inside of the process block 120 and may be a processing part configured to perform a coating process on the substrates carried through the first carrying block 110. The first chemical liquid processing part 1210 has a plurality of first processing modules 1211. The plurality of first processing modules 1211 are arranged into a plurality of columns and every column has one or more layers. For example, in an embodiment, the first chemical liquid processing part 1210 has four first processing modules 1211 and the four first processing modules 1211 are arranged into two columns and every column has two layers. Each of the first processing modules 1211 is a coating apparatus configured to form a photoresist film for forming a pattern on the substrates by coating photoresist liquid on the substrates. The second chemical liquid processing part 1220 is disposed in an upper side of the inside of the process block 120 and may be a processing part configured to perform a developing process on the substrates which are exposure-processed in the exposure apparatus and carried in the process block 120 through the second carrying block 130. The second chemical liquid processing part 1220 has a plurality of second processing modules 1221. The plurality of second processing modules 1221 are arranged into a plurality of columns and every column has one or more layers. For example, in an embodiment, the second chemical liquid processing part 1220 has four second processing modules 1221 and the four second processing modules 1221 are arranged into two columns and every column has two layers. Each of the second processing modules 1221 is a developing apparatus configured to apply a developing liquid on the substrates.

The heating processing part 1230 has a plurality of heating modules 1231. The plurality of heating modules 1231 are arranged into a plurality of columns and every column has a plurality of layers. Each of the heating modules 1231 is a heating apparatus configured to heat the substrates to a desired temperature before and after the first chemical processing on the substrates or the second chemical processing on the substrates.

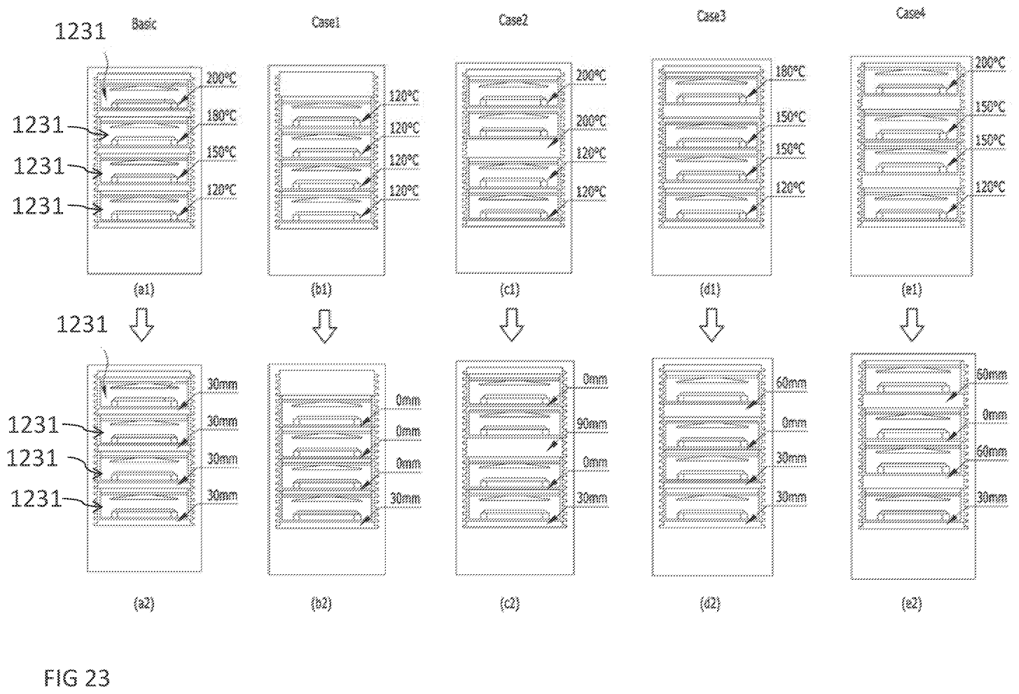

Referring to FIG. 23, in an embodiment of the present disclosure, the plurality of layers of the heating modules 1231 in every column may be configured in a wafer cassette form and the interval between the heating modules 1231 is adjustable. A method of controlling a temperature of a substrate is exemplified in FIG. 23. A heating plate arranged in each heating module 1231 may be heated in different temperatures from each other and used. For example, a heating plate set to the lowest temperature may be arranged in a heating module 1231 which is located at the lowermost layer, and a heating plate set to the highest temperature may be arranged in a heating module 1231 which is located at the uppermost layer. This is because the heating plate with the lowest temperature is arranged in the lowermost layer and therefore, is less affected by heat generated by the heating plate with the highest temperature and arranged in the uppermost layer. Hereinafter, examples are illustrated to describe five cases. In these examples, there are four heating modules 1231 configured in a wafer cassette form.

First, in a basic case, Basic, temperatures of four heating plates are different from each other, for example, 200° C., 180° C., 150° C., and 120° C. (see a1), and the four heating modules 1231 may be arranged to be spaced from each other at the same interval (for example, 30 mm) regardless of temperature differences (see a2).

In a first case, Case1, temperatures of the four heating plates are the same as each other, for example, 120° C. (see b1), and the four heating modules 1231 may be arranged at the same interval, for example, without a space (0 mm) (see b2). At this time, the heating plate arranged in the heating module 1231 of the uppermost layer may be arranged to be spaced from a top surface of the heating module 1231 at a fixed interval.

In a second case, Case2, temperatures of the four heating plates are 200° C., 200° C., 120° C., and 120° C. (see c1), and the four heating modules 1231 may be arranged in such a manner that only heating plates having different temperatures from each other to be spaced at a fixed interval, for example, only the adjacent heating modules 1231 having the heating plates of 200° C. and 120° C. to be spaced at a fixed interval (for example, 90 mm) (see c2).

In a third case, Case3, temperatures of the four heating plates are 180° C., 150° C., 150° C., and 120° C. (see d1), and the four heating modules 1231 may be arranged in such a manner that only the heating modules 1231 having the heating plates with different temperatures from each other are arranged at different intervals from each other. For example, the adjacent heating modules 1231 having heating plates of 180° C. and 150° C. may be arranged to be spaced at a fixed interval (for example, 60 mm) and the other adjacent heating modules 1231 having heating plates of 150° C. and 120° C. may be arranged to be spaced at a fixed interval (for example, 30 mm) (see d2). At this time, even when the temperature difference (30° C.) between the adjacent heating plates is the same as that (30° C.) between the other adjacent heating plates, the four heating modules 1231 may be arranged in such a manner that the adjacent heating modules 1231 having heating plates of 180° C. and 150° C. may be arranged to be spaced at an interval different from the other adjacent heating modules 1231 having heating plates of 150° C. and 120° C.

In a fourth case, Case4, temperatures of the four heating plates are 200° C., 150° C., 150° C., and 120° C. (see e1), and the four heating modules 1231 may be arranged in such a manner that only the heating modules 1231 having heating plates with different temperatures from each other are arranged in the same interval as each other. For example, the adjacent heating modules 1231 having heating plates of 200° C. and 150° C. may be arranged to be spaced at a fixed interval (for example, 60 mm) and the other adjacent heating modules 1231 having heating plates of 150° C. and 120° C. may be arranged to be spaced at a fixed interval (for example, 60 mm) (see e2). At this time, even when the temperature difference (50° C.) between the adjacent heating plates is different from that (30° C.) between the other adjacent heating plates, the four heating modules 1231 may be arranged in such a manner that the adjacent heating modules 1231 having heating plates of 200° C. and 150° C. may be arranged to be spaced at the same interval as the other adjacent heating modules 1231 having heating plates of 150° C. and 120° C.

The example that the method of controlling a temperature of a substrate has been illustrated in FIG. 23, but this is not limited thereto and the substrate temperature may be controlled by adjusting intervals between the heating modules 1231 through various methods.

It can be seen from the above description that since the temperature difference between heating plates can be controlled by adjusting the intervals between heating modules 1231, the heating plates may be controlled in different temperatures from each other. Further, the heating modules 1231 may be configured in the wafer cassette form and the plurality of heating modules 1231 are arranged in inner slots of the wafer cassette form so that the interval between the heating plates may be freely adjusted and controlled. Accordingly, the effect by heat around the heating plate may be minimized and a space between the heating plates may be easily changed according to the temperature effect.

The substrate transferring part 1240 includes at least two first robots 1241, 1242 and at least one second robot 1243. The first robots 1241, 1242 are configured to transfer the substrates between the first chemical liquid processing part 1210 and the heating processing part 1230. The first robot 1241 puts the substrates processed in the first chemical liquid processing part 1210 and the heating processing part 1230 into the first buffer unit 1251. The second robot 1243 is configured to unload the substrates from the first buffer unit 1251 and transfer the substrates to be processed in the exposure apparatus via the second carrying block 130 and the interface block 140. The second robot 1243 is also configured to take the substrates carried from the first carrying block 110 and load the substrates into the other first buffer unit 1252. The other first robot 1242 takes the substrates from the other first buffer unit 1252 and transfers the substrates to be processed in the first chemical liquid processing part 1210 and the heating processing part 1230. The second robot 1243 has a plurality of (such as five) end effectors 12431 for transferring the substrates. The second robot 1243 is configured to move along a leading rail 12432 which is disposed in the substrate transferring part 1240. A first fan filter unit (FFU) 1261 is located above the two first robots 1241, 1242 and a second fan filter unit (FFU) 1262 is located above the second robot 1243 for supplying clean gas.

In an embodiment, the second robot 1243 is arranged below the two first robots 1241, 1242 and parallel with the two first robots 1241, 1242. The leading rail 12432 is horizontally disposed in the bottom of the substrate transferring part 1240.

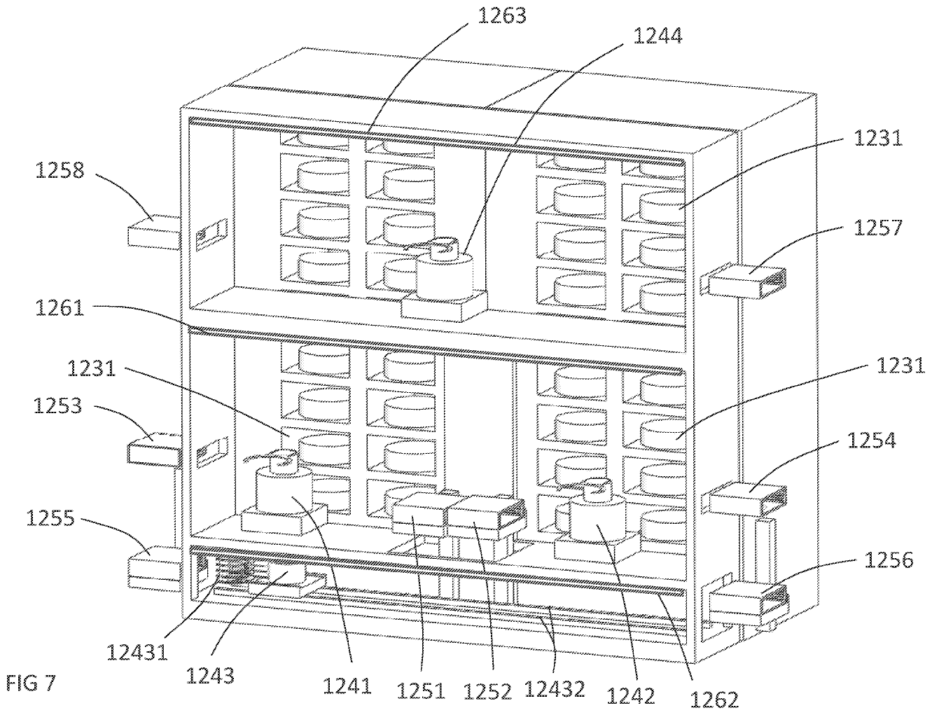

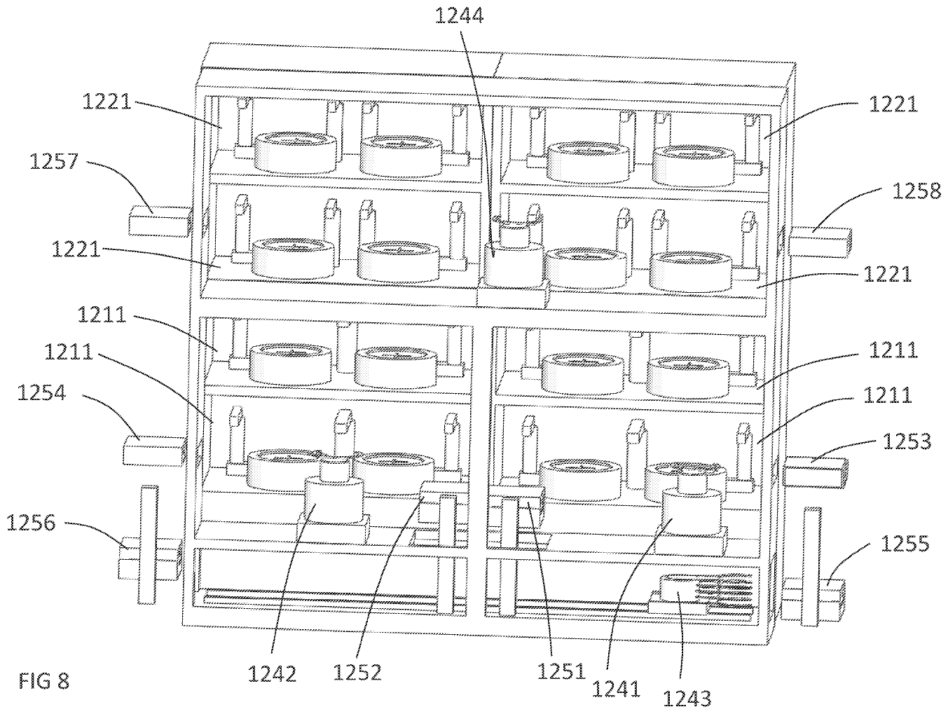

The substrate transferring part 1240 includes at least one pair of first buffer units 1251, 1252 located between the two adjacent first robots 1241, 1242. Referring to FIG. 7 and FIG. 8, a first embodiment of the first buffer units 1251, 1252 is disclosed. In this embodiment, the two first buffer units 1251, 1252 are arranged side by side and parallel to the leading rail 12432. The two first buffer units 1251, 1252 are configured to be capable of ascending and descending. For example, the two first buffer units 1251, 1252 may ascend and descend respectively along corresponding supporting frames. For processing the substrates, the first robot 1241 gets the substrates to be coating processed from the first carrying block 110 and transfers the substrates to the first processing modules 1211 and the heating modules 1231. Meantime, the first buffer unit 1252 descends and the second robot 1243 gets the substrates to be coating processed from the first carrying block 110 and transfers the substrates to the first buffer unit 1252. The first buffer unit 1252 ascends and the first robot 1242 gets the substrates from the first buffer unit 1252 and transfers the substrates to the first processing modules 1211 and the heating modules 1231. After the substrates are processed in the first processing modules 1211 and the heating modules 1231, the first robot 1241 transfers the substrates to the first buffer unit 1251. The first buffer unit 1251 descends and the second robot 1243 gets the substrates from the first buffer unit 1251 and transfers the substrates to the second carrying block 130. After the substrates are processed in the first processing modules 1211 and the heating modules 1231, the first robot 1242 transfers the substrates to the second carrying block 130.

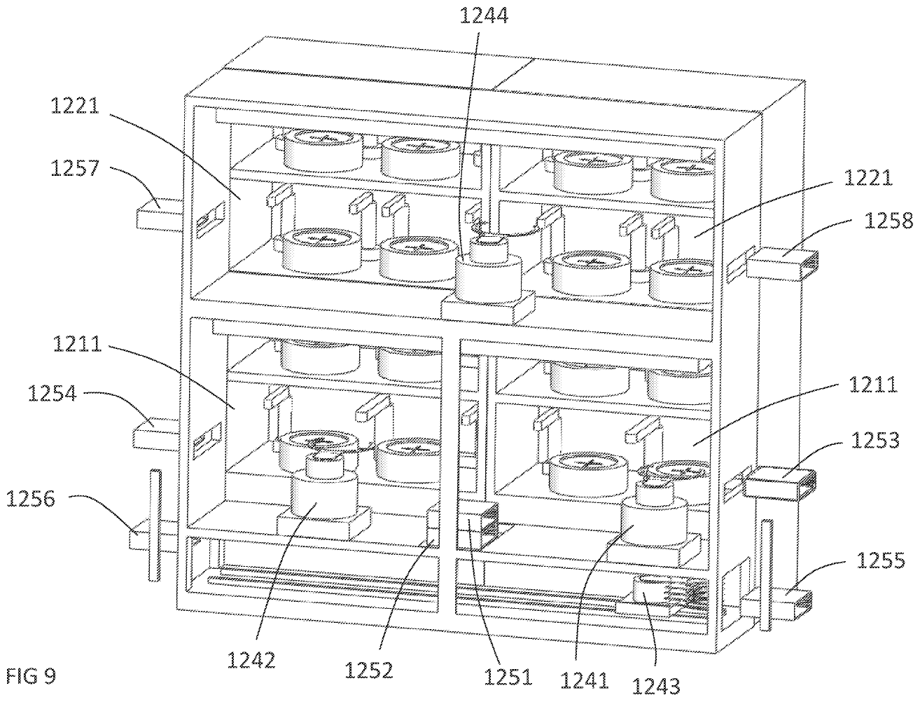

Referring to FIG. 9, a second embodiment of the first buffer units 1251, 1252 is disclosed. In this embodiment, the two first buffer units 1251, 1252 are arranged to be stacked and the two first buffer units 1251, 1252 are configured to be capable of ascending and descending. For example, the two first buffer units 1251, 1252 may ascend and descend together along a supporting frame. For processing the substrates, the first robot 1241 gets the substrates to be coating processed from the first carrying block 110 and transfers the substrates to the first processing modules 1211 and the heating modules 1231. Meantime, the first buffer units 1251, 1252 descend and the second robot 1243 gets the substrates to be coating processed from the first carrying block 110 and transfers the substrates to the first buffer unit 1252. The first buffer units 1251, 1252 ascend and the first robot 1242 gets the substrates from the first buffer unit 1252 and transfers the substrates to the first processing modules 1211 and the heating modules 1231. After the substrates are processed in the first processing modules 1211 and the heating modules 1231, the first robot 1241 transfers the substrates to the first buffer unit 1251. The first buffer units 1251, 1252 descend and the second robot 1243 gets the substrates from the first buffer unit 1251 and transfers the substrates to the second carrying block 130. After the substrates are processed in the first processing modules 1211 and the heating modules 1231, the first robot 1242 transfers the substrates to the second carrying block 130. Comparing with the first embodiment of the first buffer units 1251, 1252, this embodiment saves more space.

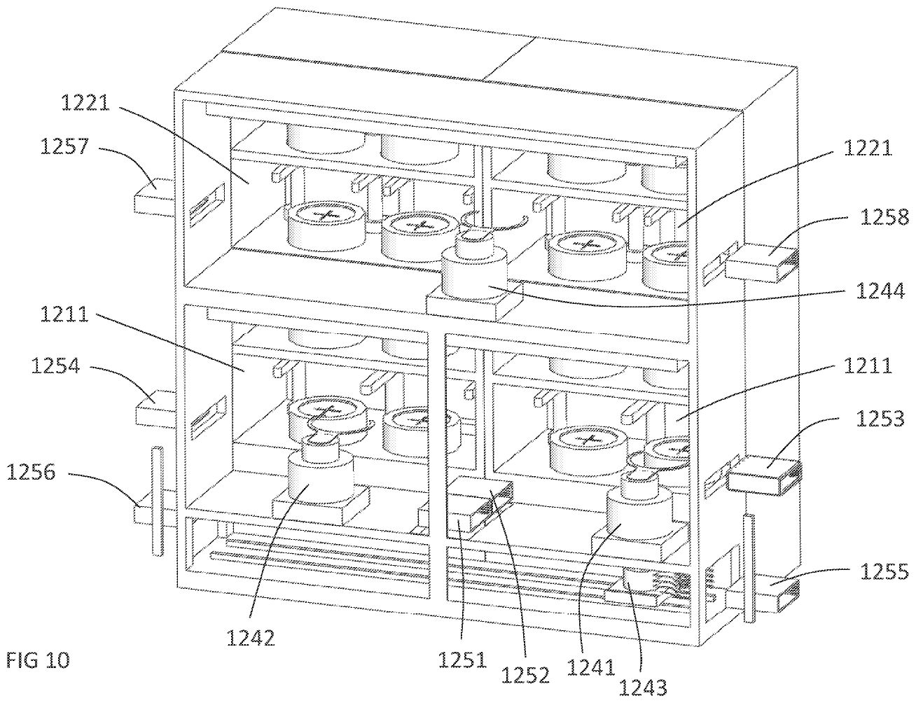

Referring to FIG. 10, a third embodiment of the first buffer units 1251, 1252 is disclosed. In this embodiment, the two first buffer units 1251, 1252 are arranged side by side and perpendicular to the leading rail 12432. The two first buffer units 1251, 1252 are configured to be capable of ascending and descending. For example, the two first buffer units 1251, 1252 may ascend and descend together along a supporting frame. For processing the substrates, the first robot 1241 gets the substrates to be coating processed from the first carrying block 110 and transfers the substrates to the first processing modules 1211 and the heating modules 1231. Meantime, the first buffer units 1251, 1252 descend and the second robot 1243 gets the substrates to be coating processed from the first carrying block 110 and transfers the substrates to the first buffer unit 1252. The first buffer units 1251, 1252 ascend and the first robot 1242 gets the substrates from the first buffer unit 1252 and transfers the substrates to the first processing modules 1211 and the heating modules 1231. After the substrates are processed in the first processing modules 1211 and the heating modules 1231, the first robot 1241 transfers the substrates to the first buffer unit 1251. The first buffer units 1251, 1252 descend and the second robot 1243 gets the substrate from the first buffer unit 1251 and transfers the substrates to the second carrying block 130. After the substrates are processed in the first processing modules 1211 and the heating modules 1231, the first robot 1242 transfers the substrates to the second carrying block 130.

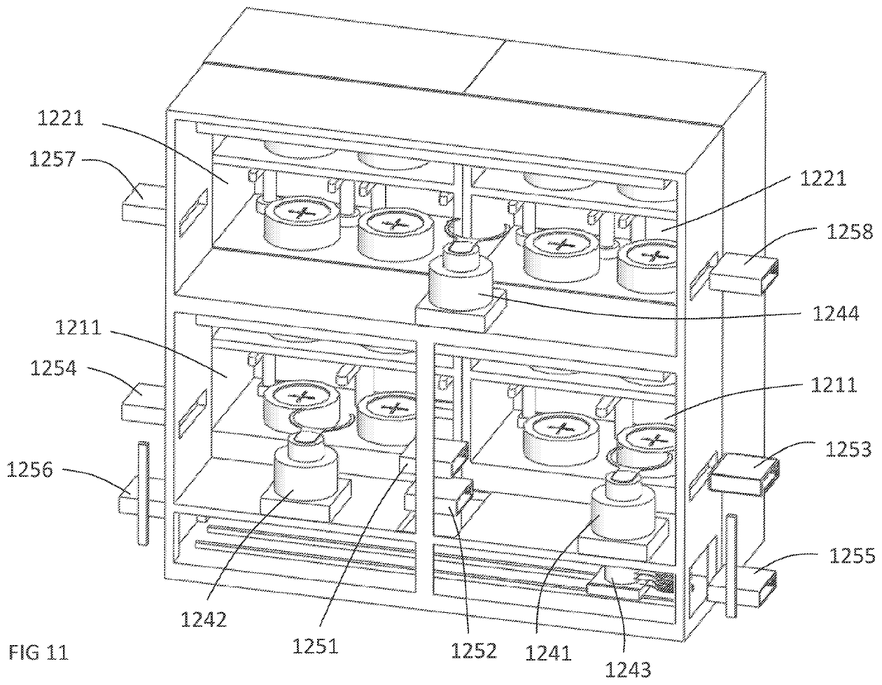

Referring to FIG. 11, a fourth embodiment of the first buffer units 1251, 1252 is disclosed. In this embodiment, the two first buffer units 1251, 1252 are arranged to be stacked and the first buffer unit 1251 located above is fixed and the other first buffer unit 1252 located below is configured to be capable of ascending and descending. For example, the first buffer unit 1252 may ascend and descend along a supporting frame. For processing the substrates, the first robot 1241 gets the substrates to be coating processed from the first carrying block 110 and transfers the substrates to the first processing modules 1211 and the heating modules 1231. Meantime, the first buffer unit 1252 descends and the second robot 1243 gets the substrates to be coating processed from the first carrying block 110 and transfers the substrates to the first buffer unit 1252. The first buffer unit 1252 ascends and the first robot 1242 gets the substrates from the first buffer unit 1252 and transfers the substrates to the first processing modules 1211 and the heating modules 1231. After the substrates are processed in the first processing modules 1211 and the heating modules 1231, the first robot 1241 transfers the substrates to the first buffer unit 1251. The first robot 1242 gets the substrates from the first buffer unit 1251 and transfers the substrates to the second carrying block 130. After the substrates are processed in the first processing modules 1211 and the heating modules 1231, the first robot 1242 transfers the substrates to the second carrying block 130.

The substrate transferring part 1240 includes at least one third robot 1244 configured to transfer the substrates between the second chemical liquid processing part 1220 and the heating processing part 1230. The third robot 1244 is configured to get the substrates to be developing processed from the second carrying block 130 and transfer the substrates to the second processing modules 1221 and the heating modules 1231. After the substrates are processed in the second processing modules 1221 and the heating modules 1231, the third robot 1244 transfers the substrates to the first carrying block 110. A third fan filter unit (FFU) 1263 is located above the third robot 1244 for supplying clean gas. The two first robots 1241, 1242, the second robot 1243 and the third robot 1244 are arranged in parallel layers in the substrate transferring part 1240.

In an exemplary embodiment of the present disclosure, the process block 120 further includes a pair of second buffer units 1253, 1254, a pair of third buffer units 1255, 1256, and at least one pair of fourth buffer units 1257, 1258. One second buffer unit 1253 is configured to be corresponding to the first carrying block 110 and the first robot 1241, and the other second buffer unit 1254 is configured to be corresponding to the other first robot 1242 and the second carrying block 130. One third buffer unit 1255 is configured to be corresponding to the first carrying block 110 and the second robot 1243 and the other third buffer unit 1256 is configured to be corresponding to the second robot 1243 and the second carrying block 130. One fourth buffer unit 1257 is configured to be corresponding to the second carrying block 130 and the third robot 1244 and the other fourth buffer unit 1258 is configured to be corresponding to the third robot 1244 and the first carrying block 110.

In one embodiment, the second robot 1243 is arranged at the bottom of the substrate transferring part 1240, and both the two third buffer units 1255, 1256 are configured to be capable of ascending and descending for facilitating the transfer of the substrates.

Hereinafter, an operation of the substrate processing apparatus 100 according to an embodiment of the present disclosure will be described with reference to the drawings. It should be recognized that the operation of the substrate processing apparatus 100 of the present disclosure may be changed according to different process requirements.

The cassette 112 in which substrates are stored may be mounted on the cassette loading part 111 of the first carrying block 110. The substrates stored in the cassette 112 may be loaded into the first carrying block 110 through the opening/closing part 113 by the first carrying unit 114 provided in the first carrying block 110.

The third buffer unit 1255 ascends. The substrates loaded into the first carrying block 110 are respectively transferred to the second buffer unit 1253 and the third buffer unit 1255 to be performed a coating process in the chemical liquid processing apparatus. The first robot 1241 gets the substrates to be coating processed from the second buffer unit 1253 and transfers the substrates to the first processing modules 1211 and the heating modules 1231. Meantime, the first buffer unit 1252 and the third buffer unit 1255 descend and the second robot 1243 gets the substrates to be coating processed from the third buffer unit 1255 and transfers the substrates to the first buffer unit 1252. The first buffer unit 1252 ascends and the first robot 1242 gets the substrates from the first buffer unit 1252 and transfers the substrates to the first processing modules 1211 and the heating modules 1231. After the substrates are processed in the first processing modules 1211 and the heating modules 1231, the first robot 1241 transfers the substrates to the first buffer unit 1251. The first buffer unit 1251 and the third buffer unit 1256 descend and the second robot 1243 gets the substrates from the first buffer unit 1251 and transfers the substrates to the third buffer unit 1256. After the substrates are processed in the first processing modules 1211 and the heating modules 1231, the first robot 1242 transfers the substrates to the second buffer unit 1254. The coating process of ARC film and photoresist film may be completed in the first chemical liquid processing part 1210.

The third buffer unit 1256 ascends. The substrates transferred to the second buffer unit 1254 and the third buffer unit 1256 are then transferred to the second carrying block 130 and then transferred to the interface block 140 via the second carrying unit 131 and the third carrying unit 141. The substrates transferred to the interface block 140 may be carried into an exposure apparatus (not shown) through the third carrying unit 141 provided in the interface block 140. The substrates that an exposure process is completed may be collected and transferred to the second carrying block 130.

The substrates carried into the second carrying block 130 may be carried into the fourth buffer unit 1257. The third robot 1244 may get the substrates from the fourth buffer unit 1257 and transfer the substrates to the second processing modules 1221 and the heating modules 1231 to perform a developing process on the substrates. The substrates that the developing process is completed may be transferred to the fourth buffer unit 1258.

The substrates in the fourth buffer unit 1258 may be collected and transferred to slots of the initial cassette 112 through the first carrying unit 114 of the first carrying block 110.

Because the requirement for the period of time (from the time that the substrates have been performed coating process to the time that the substrates are to be performed exposure process) is not too strict, and the coating process time of the substrate is shorter than the developing process time of the substrate, therefore, one first robot is capable of performing the substrates transfer of four coating units arranged in two layers or six coating units arranged in three layers, cooperating with the second robot, the burden of the first robot can be reduced. Besides, the two first robots can independently perform the substrates transfer and one first robot does not transfer the substrates to the other first robot, improving the substrate transfer efficiency and reducing particles contamination. Furthermore, since the developing process time of the substrate needs to be controlled accurately, so the substrates to be performed developing process are transferred piece by piece via the third robot.

One outstanding advantage of the substrate processing apparatus 100 of the present disclosure is that the substrate processing apparatus 100 can provide expandability options. In order to increase productivity, it can increase a plurality of first processing modules 1211, a plurality of second processing modules 1221 and a plurality of heating modules 1231. Further, in order to improve substrate transfer efficiency, it can increase the numbers of the first robots, the first buffer units and the third robots. The following will provide an example for description.

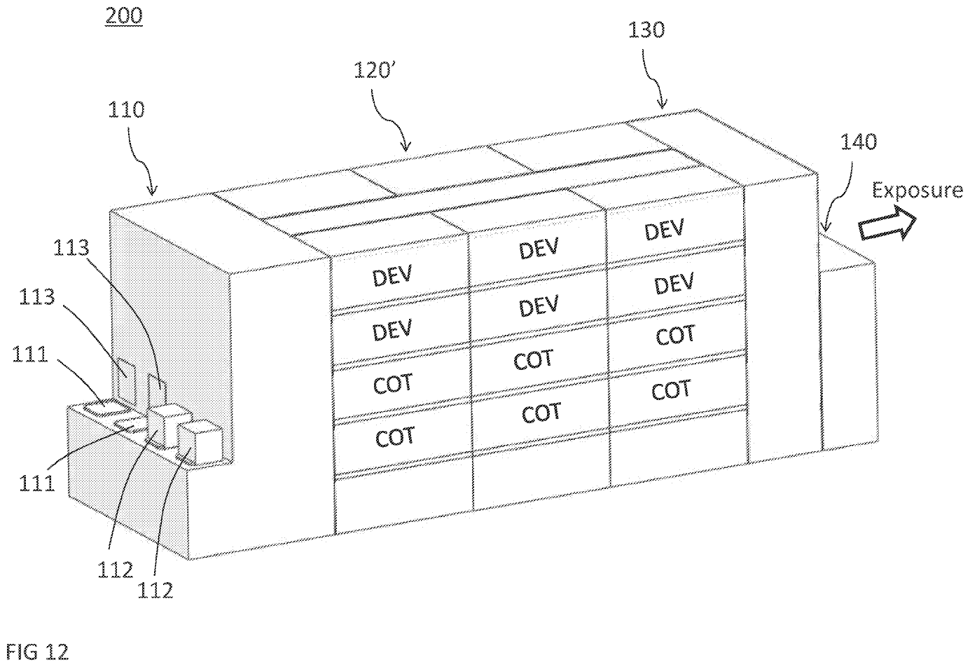

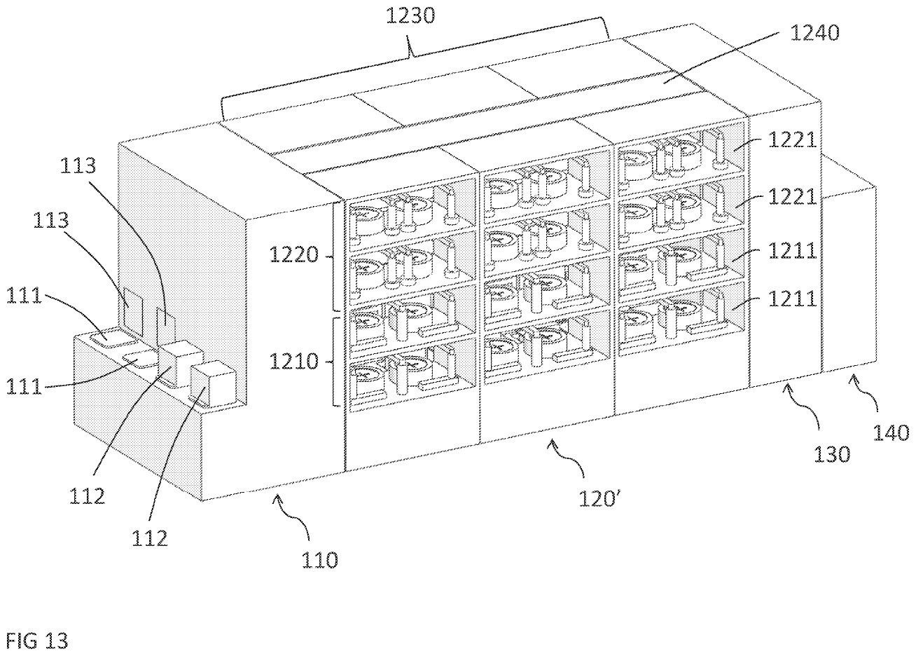

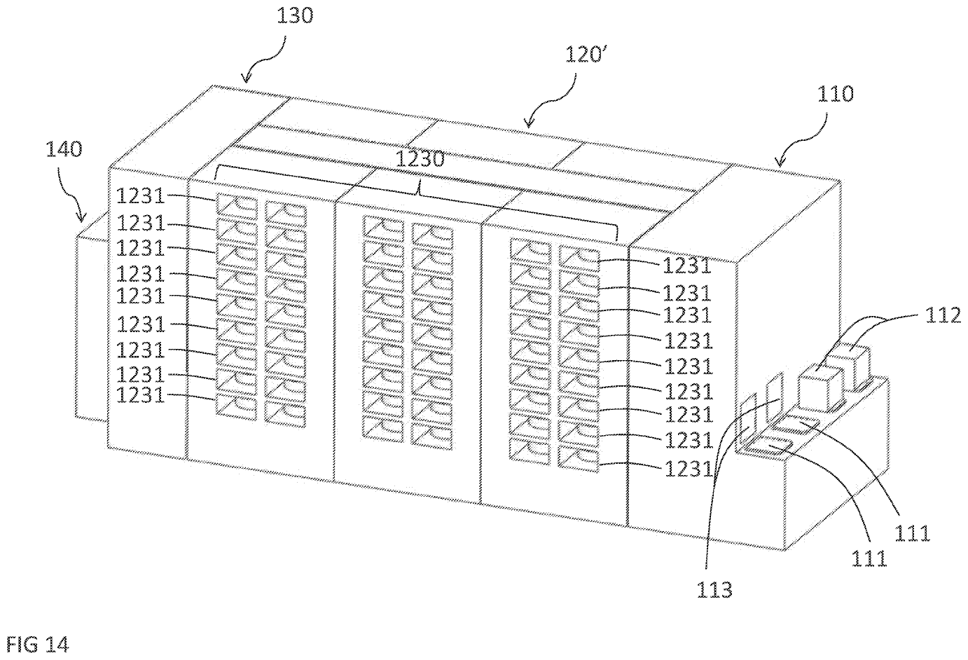

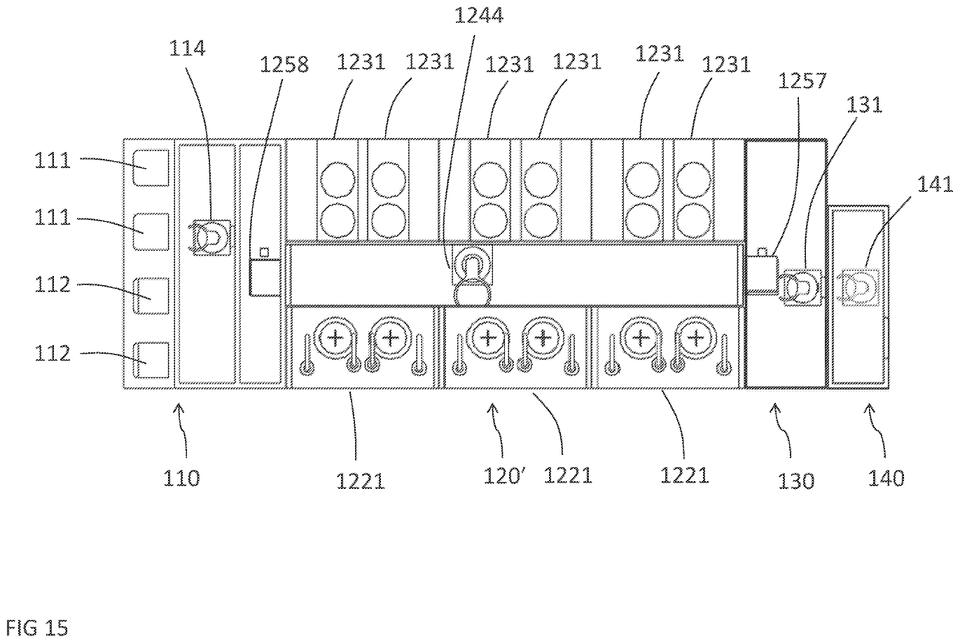

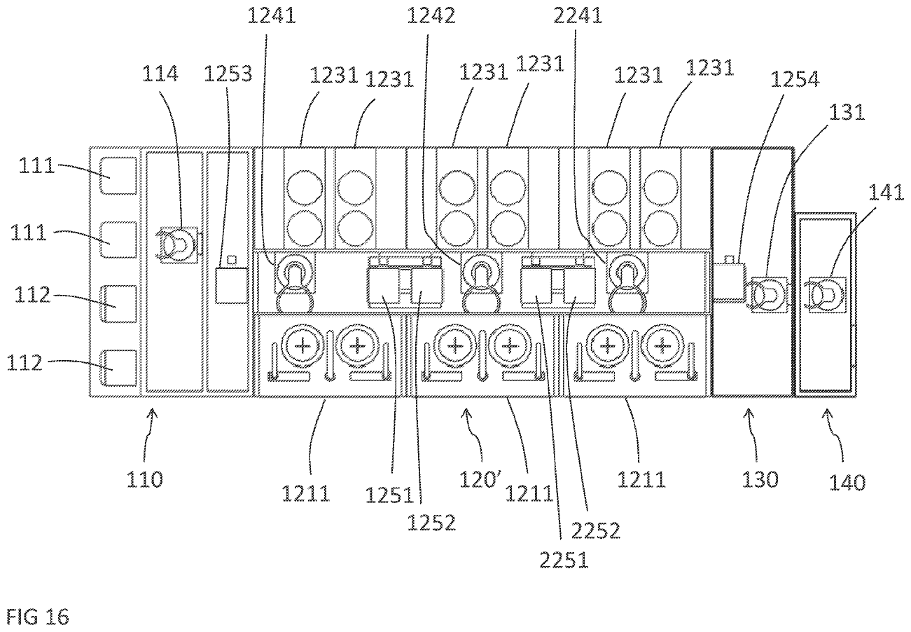

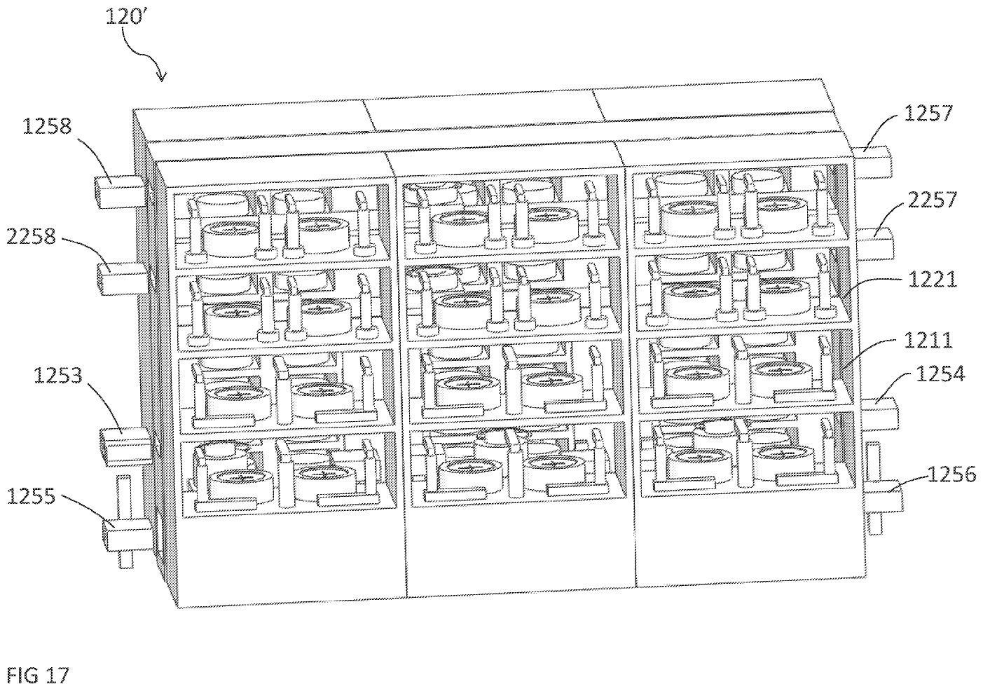

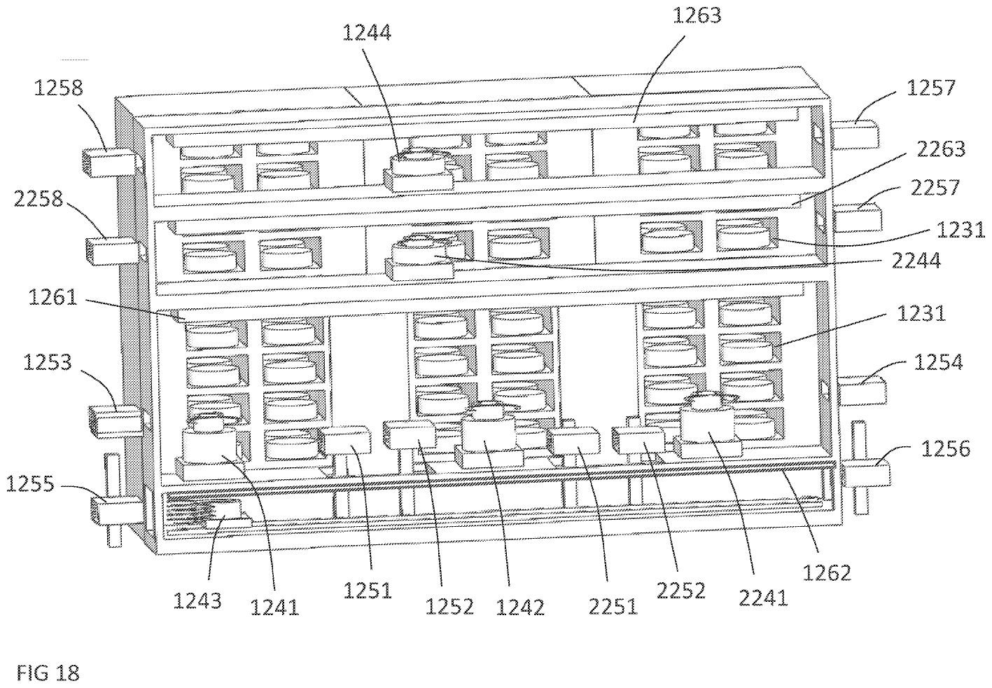

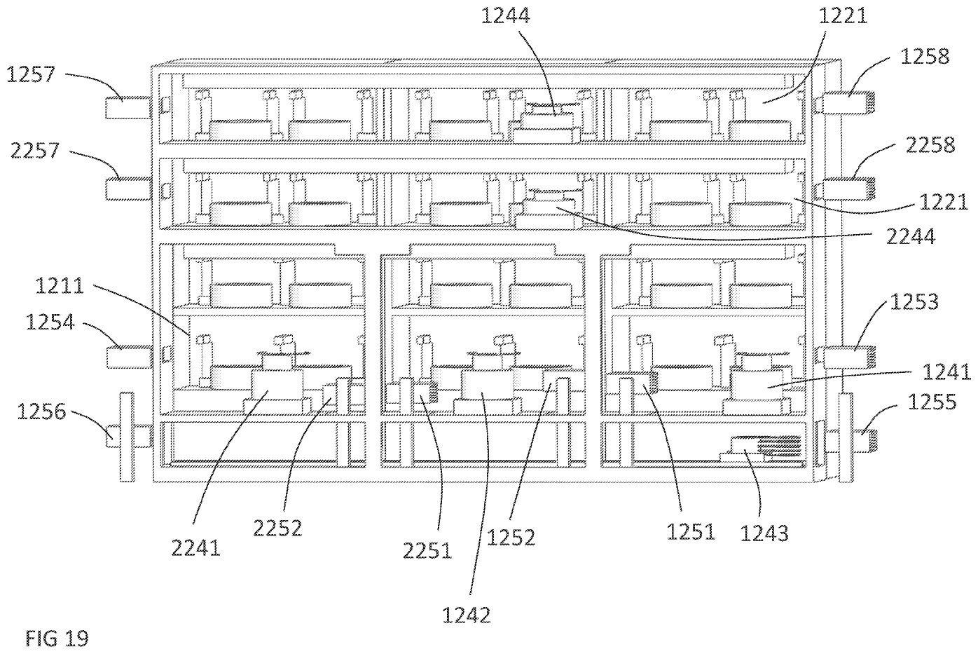

Referring to FIGS. 12 to 19, a substrate processing apparatus 200 according to another exemplary embodiment of the present disclosure is illustrated. The substrate processing apparatus 200 includes a first carrying block 110, a process block 120′, a second carrying block 130 and an interface block 140. The configuration of the first carrying block 110, the second carrying block 130 and the interface block 140 may be as same as that of the substrate processing apparatus 100, so that the first carrying block 110, the second carrying block 130 and the interface block 140 will not be described herein repeatedly.

Comparing with the process block 120 of the substrate processing apparatus 100, the process block 120′ of the substrate processing apparatus 200 may be regarded as extending a plurality of first processing modules 1211, a plurality of second processing modules 1221 and a plurality of heating modules 1231 on the basis of the process block 120. In this embodiment, the process block 120′ has six first processing modules 1211 and six second processing modules 1221, both of which are arranged in three columns and every column has two layers.

In order to improve the substrate transfer efficiency, the process block 120′ further includes another first robot 2241 corresponding to the added first processing modules 1211. Another pair of first buffer units 2251, 2252 is added and disposed between the two adjacent first robots 2241, 1242. The process block 120′ further includes another third robot 2244 which is arranged in parallel with the third robot 1244. Correspondingly, another third fan filter unit (FFU) 2263 is located above the third robot 2244 and another pair of fourth buffer units 2257, 2258 is configured to be corresponding to the third robot 2244. One fourth buffer unit 2257 is configured to be corresponding to the second carrying block 130 and the third robot 2244, and the other fourth buffer unit 2258 is configured to be corresponding to the third robot 2244 and the first carrying block 110. The third robot 1244 may be located above the other third robot 2244 and is in charge of transferring the substrates between the second processing modules 1221 of the upper layer and the heating modules 1231. The other third robot 2244 is in charge of transferring the substrates between the second processing modules 1221 of the lower layer and the heating modules 1231.

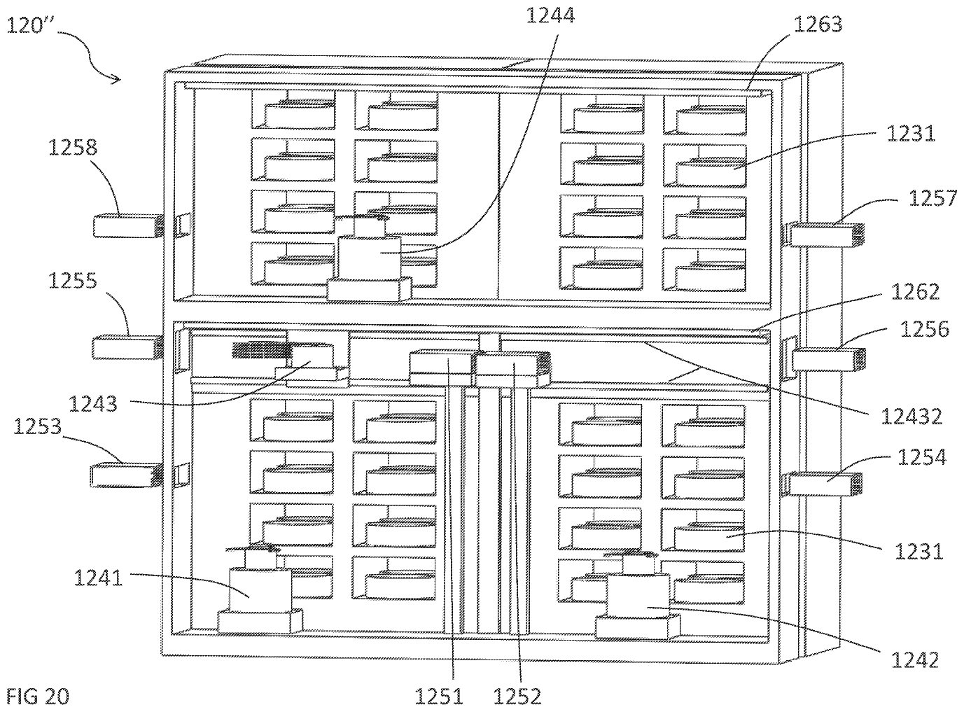

Referring to FIG. 20, a process block hiding first processing modules and second processing modules according to another embodiment of the present disclosure is illustrated. In this embodiment, the process block 120″ is substantially as same as the process block 120 and the difference is that in the process block 120″, the second robot 1243 is arranged above the two first robots 1241, 1242. The leading rail 12432 of the second robot 1243 is vertically disposed on a side wall of the substrate transferring part 1240. The pair of third buffer units 1255, 1256 corresponding to the second robot 1243 is located above the pair of second buffer units 1253, 1254 corresponding to the two first robots 1241, 1242. Because the position of the second robot 1243 is relatively high and the second robot 1243 may easily take the substrates to be processed from the third buffer unit 1255 and load the processed substrates to the third buffer unit 1256, therefore, the pair of third buffer units 1255, 1256 may not be necessary to ascend and descend. Besides, the first robots 1241, 1242 and the second robot 1243 may share one fan filter unit (FFU) 1262 which is disposed above the second robot 1243 and the first fan filter unit (FFU) 1261 located above the first robots 1241, 1242 may be omitted.

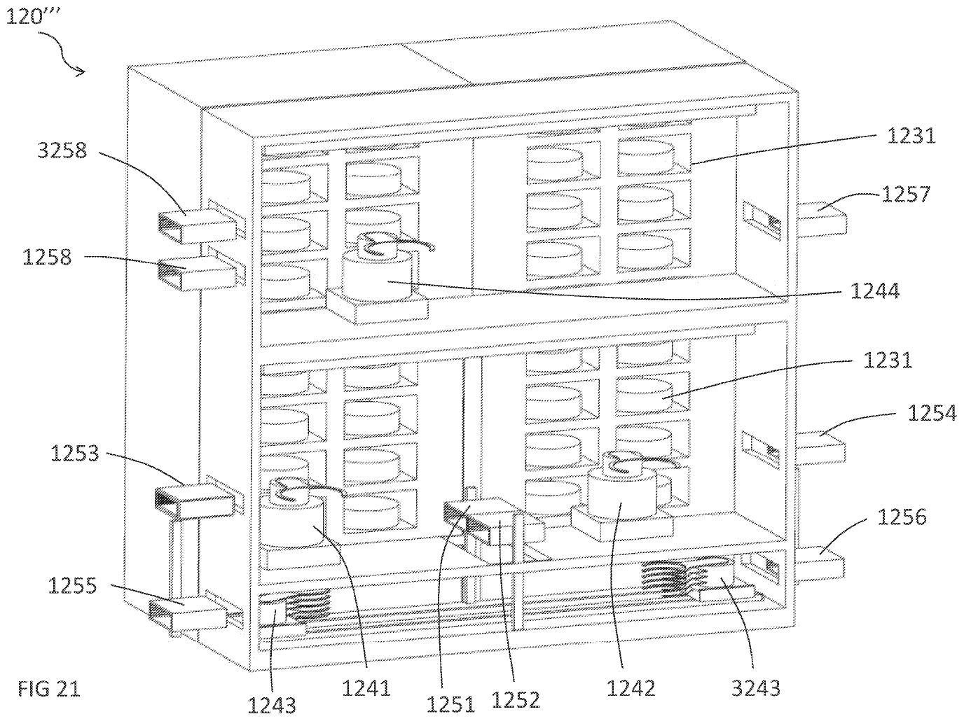

Referring to FIG. 21, a process block hiding first processing modules and second processing modules according to yet another embodiment of the present disclosure is illustrated. In this embodiment, the process block 120′″ is substantially as same as the process block 120 and the difference is that the process block 120′″ further includes another second robot 3243 and another fourth buffer unit 3258. The two second robots 1243, 3243 are arranged to be parallel with the first robots 1241, 1242 and located at both sides of the first buffer units 1251, 1252. Specifically, the two second robots 1243, 3243 are arranged below the first robots 1241, 1242. The two second robots 1243, 3243 share the same leading rail. The first buffer units 1251, 1252 are arranged side by side and the arrangement direction of the first buffer units 1251, 1252 is perpendicular to the leading rail. The first buffer units 1251, 1252 are configured to be capable of ascending and descending. The first buffer units 1251, 1252 are located between the two first robots 1241, 1242. For processing the substrates, the first robot 1241 takes the substrates to be coating processed from the second buffer unit 1253 and transfers the substrates to the first processing modules 1211 and the heating modules 1231. Meantime, the first buffer unit 1252 descends and the second robot 1243 takes the substrates to be coating processed from the third buffer unit 1255 and transfers the substrates to the first buffer unit 1252. The first buffer unit 1252 ascends and the first robot 1242 takes the substrates from the first buffer unit 1252 and transfers the substrates to the first processing modules 1211 and the heating modules 1231. After the substrates are processed in the first processing modules 1211 and the heating modules 1231, the first robot 1241 transfers the substrates to the first buffer unit 1251. The first buffer unit 1251 descends and the second robot 3243 takes the substrates from the first buffer unit 1251 and transfers the substrates to the third buffer unit 1256. After the substrates are processed in the first processing modules 1211 and the heating modules 1231, the first robot 1242 transfers the substrates to the second buffer unit 1254.

The substrate processing apparatus of the present disclosure may perform both coating process and developing process. Alternatively, the substrate processing apparatus of the present disclosure may perform either coating process or developing process. Taking only performing the developing process for example, the third robot 1244 takes the substrates to be developing processed from the fourth buffer unit 1258 and transfers the substrates to the second processing modules 1221 and the heating modules 1231. After the substrates are processed in the second processing modules 1221 and the heating modules 1231, the third robot 1244 transfers the substrates to the other fourth buffer unit 3258 and the substrates in the fourth buffer unit 3258 may be collected and transferred to slots of the initial cassette 112 through the first carrying unit 114 of the first carrying block 110. It should be recognized that the application of these buffer units may be adjusted according to process requirements in order to realize different process purpose.

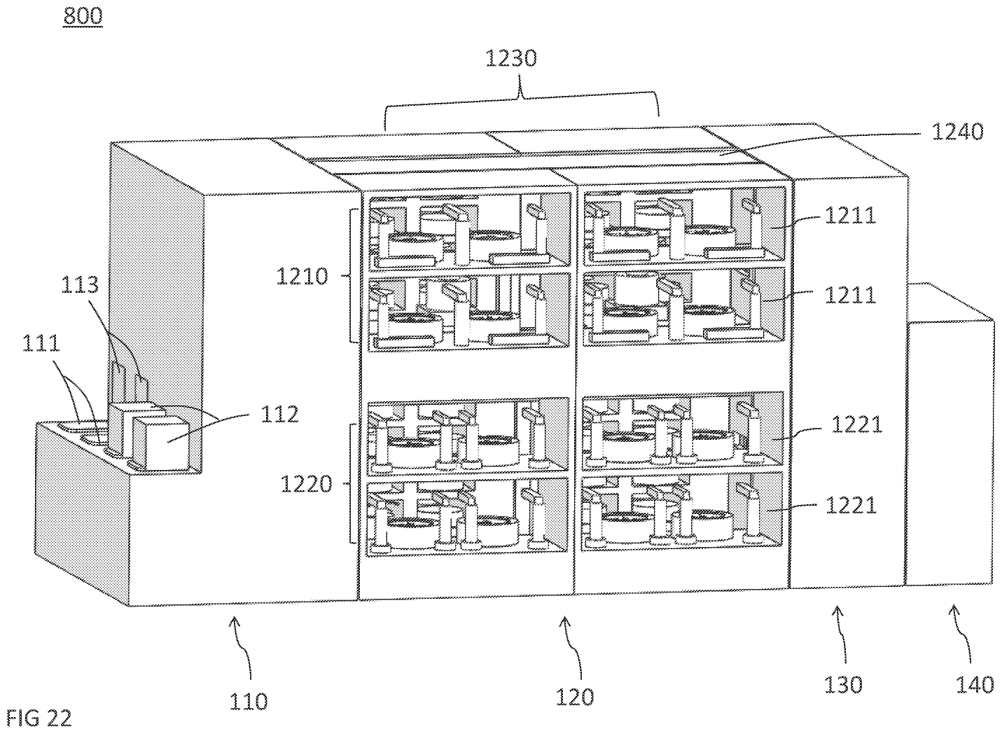

Referring to FIG. 22, a substrate processing apparatus according to another exemplary embodiment of the present disclosure is illustrated. The substrate processing apparatus 800 is substantially as same as the substrate processing apparatus 100 and the difference is that in the substrate processing apparatus 800, the first chemical liquid processing part 1210 having a plurality of first processing modules 1211 is located above the second chemical liquid processing part 1220 having a plurality of second processing modules 1221 in the inside of the process block 120, and correspondingly, the at least two first robots and the at least one second robot are arranged above the at least one third robot.

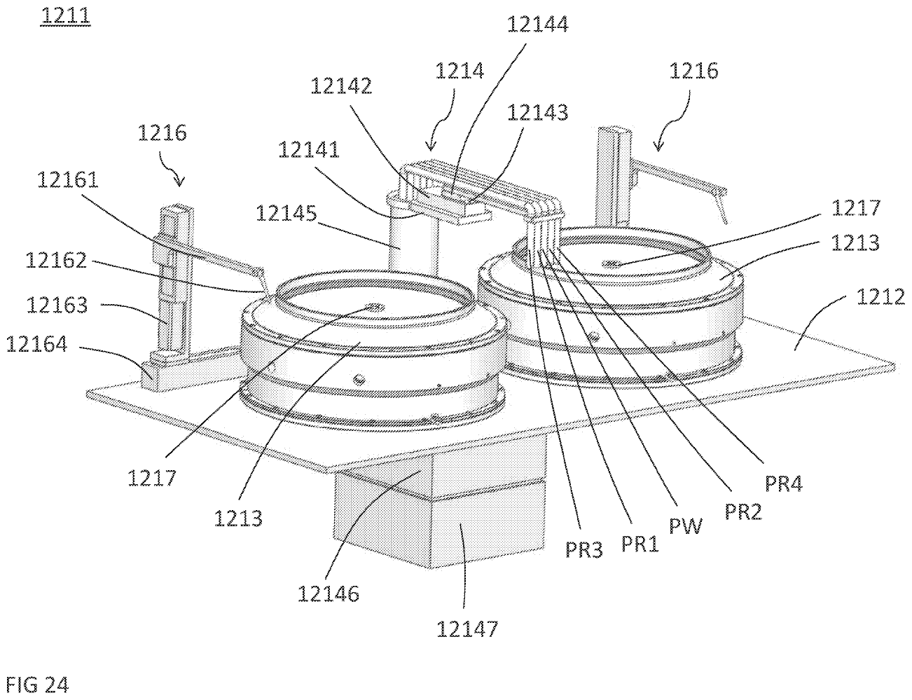

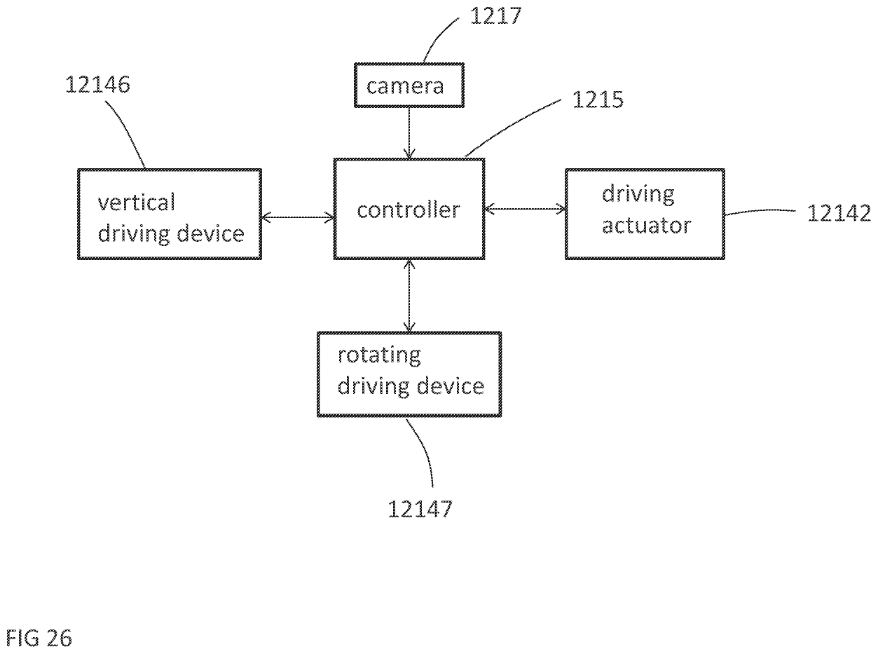

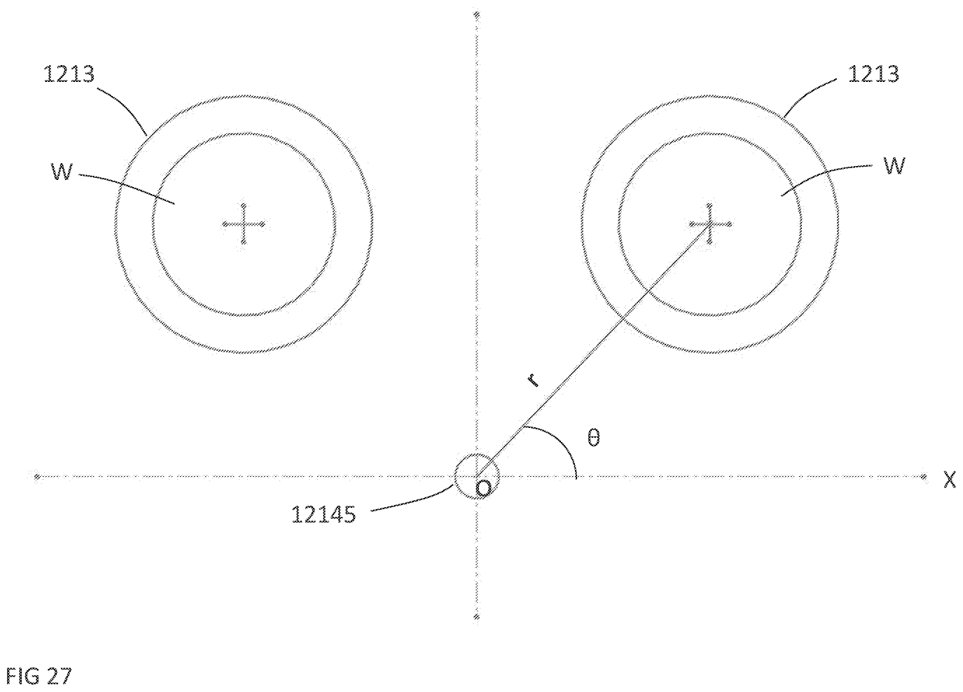

Referring to FIG. 24, FIG. 26 and FIG. 27, the first processing module 1211 may be a coating module disposed in the chemical liquid processing apparatus. The coating module 1211 includes a supporting platform 1212, two coating units 1213 arranged on the supporting platform 1212, a coating nozzle apparatus 1214 located at the center between the two coating units 1213, two edge cleaning apparatuses 1216 and a controller 1215.

The coating nozzle apparatus 1214 has a supporting arm 12141 horizontally arranged, a driving actuator 12142 configured to be positioned on the supporting arm 12141, a nozzle holder 12144 configured to be connected to the driving actuator 12142 and driven to move forward or backward by the driving actuator 12142, at least one nozzle configured to be fixed with the nozzle holder 12144, a supporting shaft 12145 configured to be fixed with the supporting arm 12141, a vertical driving device 12146 configured to be connected to the supporting shaft 12145 to drive the supporting shaft 12145 to move upward or downward and a rotating driving device 12147 configured to be connected to the supporting shaft 12145 to drive the supporting shaft 12145 to rotate. In an embodiment, the driving actuator 12142 has a sliding recess 12143. An end of the nozzle holder 12144 is disposed in the sliding recess 12143 and is configured to move forward or backward in the sliding recess 12143 by the driving of the driving actuator 12142. The driving actuator 12142 may be a linear motor. The nozzle is a coating nozzle applied for dispensing photoresist liquid to the substrates positioned in the two coating units 1213 arranged in the same row and the coating nozzle is located in the center between the two coating units 1213. The coating nozzle includes a solvent nozzle PW configured to dispense a solvent to the substrates and a plurality of chemical liquid nozzles PR, for example PR1, PR2, PR3, PR4, configured to dispense photoresist liquid to the substrates. The solvent nozzle PW is located at the center among the plurality of chemical liquid nozzles PR1, PR2, PR3, PR4 to dispense the solvent to the substrates, so that surfaces of the substrates are hydrophilic before the photoresist liquid is dispensed from the plurality of chemical liquid nozzles PR1, PR2, PR3, PR4. Pipelines respectively connecting to the solvent nozzle and the plurality of chemical liquid nozzles pass through the supporting shaft 12145 and the supporting arm 12141 and there is a space set in the supporting shaft 12145 and the supporting arm 12141 for the pipe lines moving in the space.

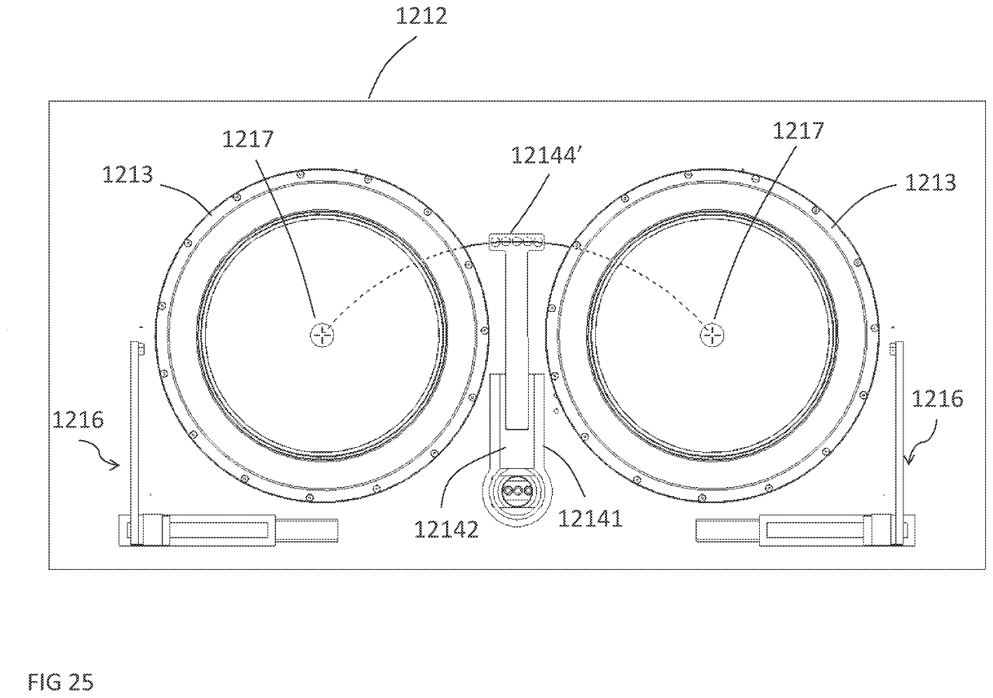

In another embodiment, as shown in FIG. 25, for facilitating the coating nozzle aligning with the center of the substrates respectively positioned in the two coating units 1213, an end of a nozzle holder 12144′ has a plurality of, such as five holes for mounting a solvent nozzle PW and a plurality of chemical liquid nozzles such as PR1, PR2, PR3, PR4. The center of the holes and the center of the two coating units 1213 are on the same arc.

Each of the edge cleaning apparatuses 1216 is corresponding to one coating unit 1213 and configured to remove the photoresist film formed on the edge of the substrate positioned in the coating unit 1213. Every edge cleaning apparatus 1216 includes a dispenser holder 12161 and a dispenser 12162 mounted on an end of the dispenser holder 12161 for dispensing cleaning liquid on the edge of the substrate to remove the photoresist film formed on the edge of the substrate. The other end of the dispenser holder 12161 is connected to a vertical driving actuator 12163. The vertical driving actuator 12163 is configured to drive the dispenser holder 12161 to move vertically to adjust the distance between the dispenser 12162 and the substrate. A horizontal driving actuator 12164 is configured to drive the dispenser holder 12161 together with the vertical driving actuator 12163 to move horizontally to adjust the removing width of the photoresist film formed on the edge of the substrate.

The controller 1215 is configured to be respectively connected to the driving actuator 12142, the vertical driving device 12146 and the rotating driving device 12147 of the coating nozzle apparatus 1214 and be capable of controlling the coating nozzle to align with the center of the substrates positioned in the two coating units 1213 arranged in the same row. The controller 1215 is also configured to be respectively connected to the vertical driving actuator 12163 and the horizontal driving actuator 12164 of the edge cleaning apparatus 1216 and be capable of controlling the removing width of the photoresist film formed on the edge of the substrate.

As shown in FIG. 26 and FIG. 27, before the coating nozzle is employed to dispense the photoresist liquid to the substrates in the two coating units 1213, it is essential to adjust each nozzle to align with the center of the substrates in the two coating units 1213. An adjusting method may include the following steps:
step 1: establishing polar coordinates in the controller 1215, and the polar point O is on the axis of the supporting shaft 12145 and the polar axis OX is parallel to the line across the central points of the two coating units 1213 arranged in the same row;
step 2: obtaining a polar point of each nozzle and recording the polar point of each nozzle in the controller 1215, wherein the polar point of each nozzle aligns the center of the substrate in the coating unit 1213; and
step 3: the controller 1215 sending instructs to the rotating driving device 12147 and the driving actuator 12142 based on the polar point of each nozzle recorded in the controller 1215 to make each nozzle reach the polar point so that the nozzle aligns with the center of the substrate which needs to be processed in the coating unit 1213. For example, if the nozzle PR1 is used to dispense photoresist liquid on the substrate in the coating unit 1213, the controller 1215 instructs the rotating driving device 12147 and the driving actuator 12142 to drive the nozzle holder 12144 to rotate and linearly move to make the nozzle PR1 be located at the polar point P(r1, θ1) of the nozzle PR1 so that the nozzle PR1 aligns with the center of the substrate.

In the step 2, a method of obtaining a polar point of each nozzle further includes:
firstly, putting a standard sample W in the coating unit 1213 and a camera 1217 being positioned at the center of the standard sample W and connected to the controller 1215, wherein the center of the standard sample W is aligned with a center of a chuck which is disposed in the coating unit 1213 for positioning and holding the substrate;
secondly, the rotating driving device 12147 driving the supporting shaft 12145 to rotate to make the nozzle (for example, PR4) align with the camera 1217, if the camera 1217 captures the nozzle PR4, record the polar point P(r4, θ4) of the nozzle PR4 in the controller 1215, wherein r4 is a length L which is the distance from the nozzle PR4 to the polar point O, θ4 is the rotation angle of the nozzle PR4; if the camera 1217 doesn't capture the nozzle PR4, the driving actuator 12142 drives the nozzle holder 12144 to linearly move to make the nozzle PR4 move forward or backward until the camera 1217 captures the nozzle PR4, record the polar point P(r4, θ4) of the nozzle PR4 in the controller 1215, wherein r4 is a length L±σ, +σ is the distance that the driving actuator 12142 drives the nozzle PR4 to move forward, −σ is the distance that the driving actuator 12142 drives the nozzle PR4 to move backward, θ4 is the rotation angle of the nozzle PR4.

Take the same way can obtain the polar point P(r2, θ2) of the nozzle PR2, the polar point P(r, θ) of the nozzle PW, the polar point P(r1, θ1) of the nozzle PR1, the polar point P(r3, θ3) of the nozzle PR3.

The present disclosure employs the swinging type of coating nozzle apparatus 1214, which can save space. For this swinging type of coating nozzle apparatus 1214, the difficulty is alignment. Therefore, the present disclosure designs the nozzle holder 12144 connected to the driving actuator 12142 and driven to move forward or backward by the driving actuator 12142 so that the coating nozzle apparatus 1214 of the present disclosure is capable of automatically adjusting the alignment of the coating nozzle before the coating nozzle dispenses chemical liquid to substrates, and the solvent nozzle PW is at the center among the plurality of chemical liquid nozzles, such as PR3, PR1, PW, PR2, PR4, improving process efficiency by reducing a moving distance and a moving time of a nozzle.

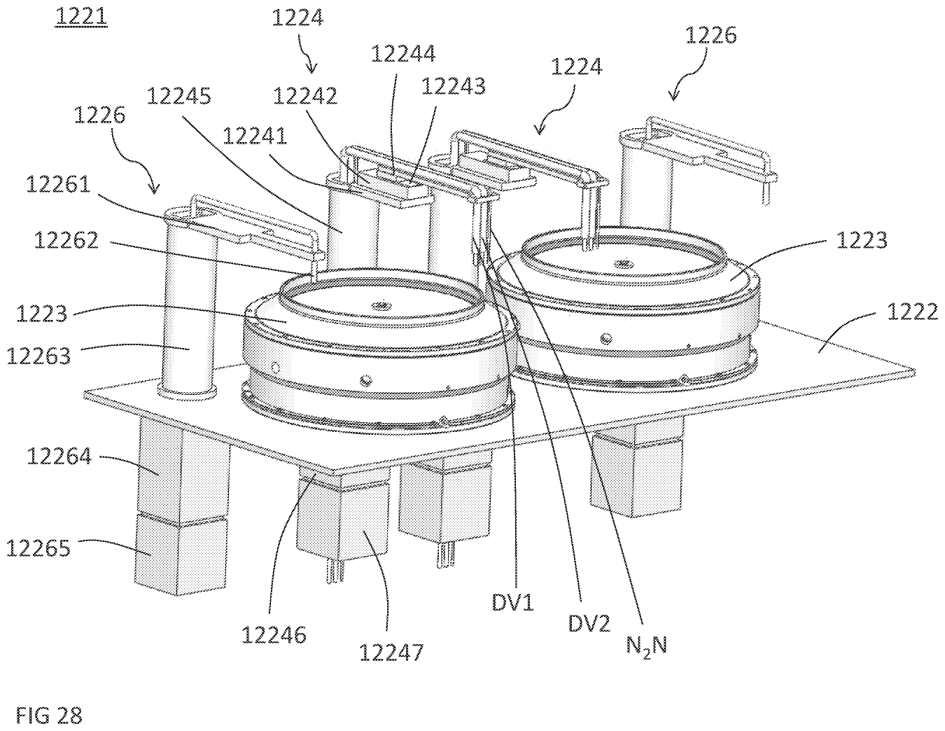

Referring to FIG. 28, the second processing module 1221 may be a developing module disposed in the chemical liquid processing apparatus. The developing module 1221 includes a supporting platform 1222, two developing units 1223 arranged on the supporting platform 1222, two developing nozzle apparatuses 1224, two rinse nozzle apparatuses 1226 and a controller. Every developing nozzle apparatus 1224 and every rinse nozzle apparatus 1226 are corresponding to one developing unit 1223.

The configuration of the coating nozzle apparatus 1214 and the developing nozzle apparatus 1224 is substantially the same except that the type of nozzles and the number of nozzles are different. Each of the developing nozzle apparatuses 1224 includes a supporting arm 12241 horizontally disposed, a driving actuator 12242 configured to be positioned on the supporting arm 12241, a nozzle holder 12244 configured to be connected to the driving actuator 12242 and driven to move forward or backward by the driving actuator 12242, at least one nozzle configured to be fixed with the nozzle holder 12244, a supporting shaft 12245 configured to be fixed with the supporting arm 12241, a vertical driving device 12246 configured to be connected to the supporting shaft 12245 to drive the supporting shaft 12245 to move upward or downward and a rotating driving device 12247 configured to be connected to the supporting shaft 12245 to drive the supporting shaft 12245 to rotate. In an embodiment, the driving actuator 12242 has a sliding recess 12243. An end of the nozzle holder 12244 is disposed in the sliding recess 12243 and is configured to move forward or backward in the sliding recess 12243 by the driving of the driving actuator 12242. The driving actuator 12242 may be a linear motor. The nozzle is a developing nozzle applied for dispensing developing liquid to the substrate positioned in one developing unit 1223. The developing nozzle includes a plurality of chemical liquid nozzles DV, for example DV1, DV2, configured to dispense developing liquid to the substrate and a gas nozzle N₂N configured to dispense non-reactive gas, such as inert gas or N₂ gas to the substrate to prevent the developing liquid from being rebounded to the substrate so as to prevent pattern defects and reduce particles contamination. Pipelines respectively connecting to the plurality of nozzles pass through the supporting shaft 12245 and the supporting arm 12241 and there is a space set in the supporting shaft 12245 and the supporting arm 12241 for the pipe lines moving in the space.

Similarly, for facilitating the developing nozzle aligning with the center of the substrate positioned in the developing unit 1223, preferably, an end of the nozzle holder 12244 has a plurality of holes for mounting the gas nozzle N₂N and the plurality of chemical liquid nozzles. The center of the holes and the center of the developing unit 1223 are on the same arc.

Each of the rinse nozzle apparatuses 1226 includes a rinse nozzle holder 12261 and a rinse nozzle 12262 is mounted on the rinse nozzle holder 12261 for spraying liquid to rinse the substrate. The rinse nozzle holder 12261 is fixed on an end of a supporting member 12263. The other end of the supporting member 12263 is configured to be connected to a vertical driving unit 12264 for driving the supporting member 12263 to move vertically and a rotating driving unit 12265 for driving the supporting member 12263 to rotate.

The controller is configured to be respectively connected to the driving actuator 12242, the vertical driving device 12246 and the rotating driving device 12247 of the developing nozzle apparatus 1224 and be capable of controlling the developing nozzle to align with the center of the substrate positioned in the developing unit 1223. The controller is also configured to be respectively connected to the vertical driving unit 12264 and the rotating driving unit 12265 of the rinse nozzle apparatus 1226 and be capable of controlling the move of the rinse nozzle 12262.

Before the developing nozzle is employed to dispense the developing liquid to the substrate in the developing unit 1223, it is essential to adjust each of the plurality of nozzles to align with the center of the substrate. The adjusting method is as same as that of the coating nozzle and will not be described herein repeatedly.

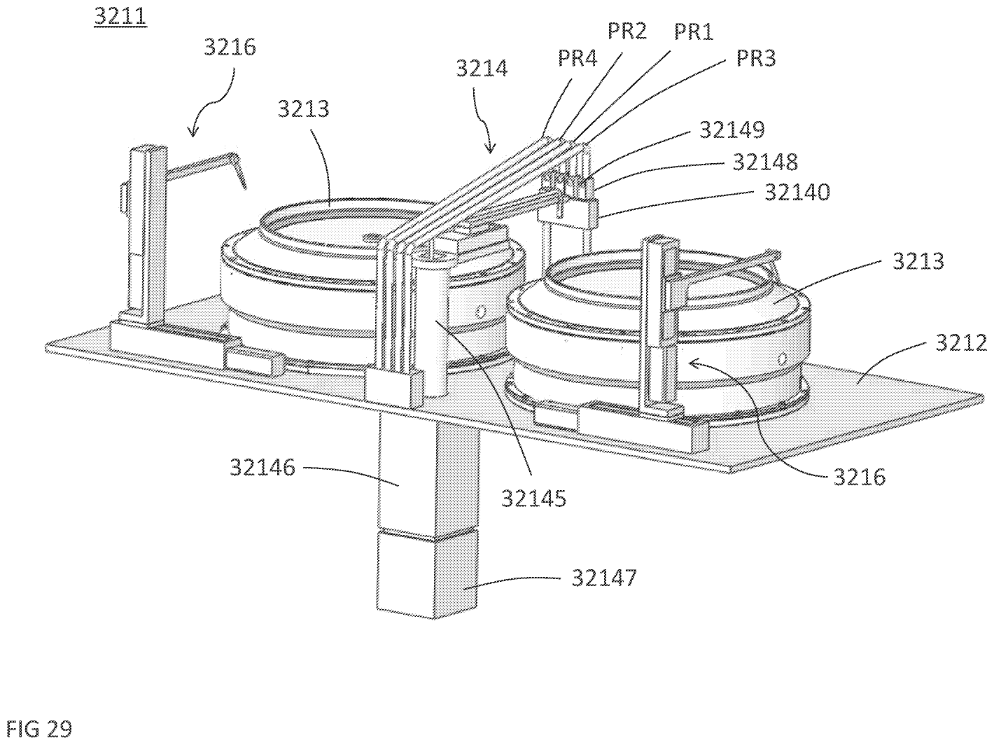

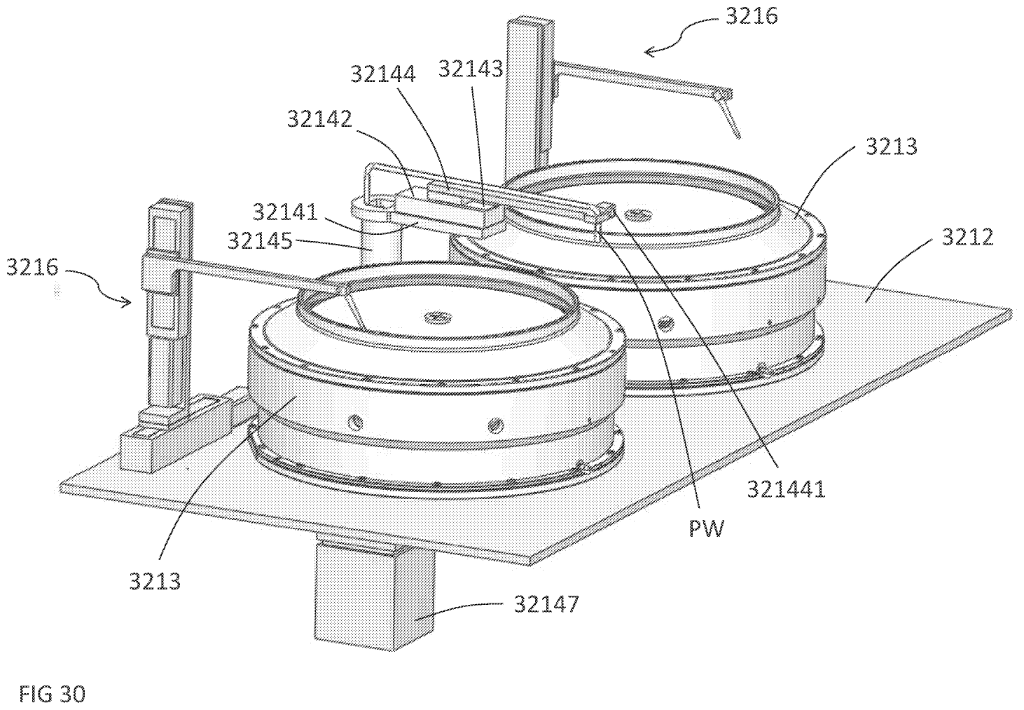

With reference to FIG. 29 to FIG. 31, a coating module according to another exemplary embodiment of the present disclosure is illustrated. The coating module 3211 has a supporting platform 3212, two coating units 3213 arranged on the supporting platform 3212, a coating nozzle apparatus 3214 located at the center between the two coating units 3213, two edge cleaning apparatuses 3216 and a controller.

The coating nozzle apparatus 3214 has a supporting arm 32141 horizontally arranged, a driving actuator 32142 configured to be positioned on the supporting arm 32141, a nozzle holder 32144 configured to be connected to the driving actuator 32142 and driven to move forward or backward by the driving actuator 32142, a solvent nozzle PW configured to be fixed with the nozzle holder 32144 for dispensing a solvent to the substrates positioned in the two coating units 3213, a supporting shaft 32145 configured to be fixed with the supporting arm 32141, a vertical driving device 32146 configured to be connected to the supporting shaft 32145 to drive the supporting shaft 32145 to move upward or downward and a rotating driving device 32147 configured to be connected to the supporting shaft 32145 to drive the supporting shaft 32145 to rotate. In an embodiment, the driving actuator 32142 has a sliding recess 32143. An end of the nozzle holder 32144 is disposed in the sliding recess 32143 and is configured to move forward or backward in the sliding recess 32143 by the driving of the driving actuator 32142. The driving actuator 32142 may be a linear motor. The other end of the nozzle holder 32144 protrudes forward to form an inserting pin 321441. The coating nozzle apparatus 3214 has a plurality of chemical liquid nozzles PR, for example PR1, PR2, PR3, PR4, configured to dispense photoresist liquid to the substrates positioned in the two coating units 3213. Each of the chemical liquid nozzles PR is configured to be set in a casing member 32148 and pass through the casing member 32148. A side wall of the casing member 32148 which is opposite to the other end of the nozzle holder 32144 sets a pin hole 32149. The plurality of casing members 32148 is arranged in a trough 32140. The trough 32140 may be supported above the supporting platform 3212 via such as a pair of support pillars. The inside of the trough 32140 may be divided into a plurality of separate areas and every area is accommodated one casing member 32148.

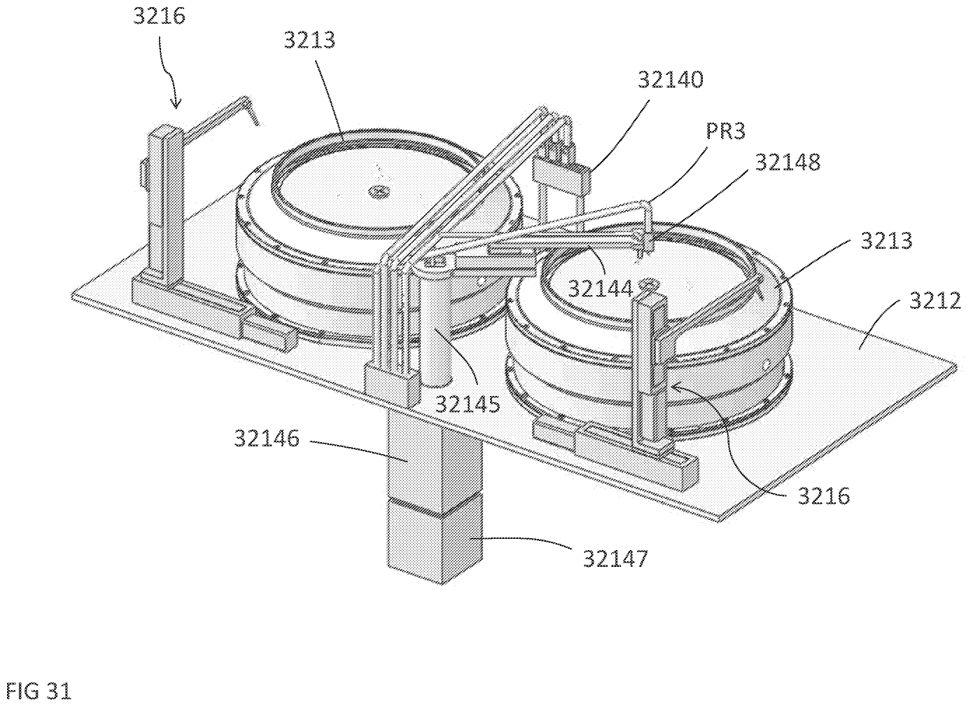

When the chemical liquid nozzles PR are used to deliver photoresist liquid to the substrates positioned in the two coating units 3213, as shown in FIG. 31, taking the chemical liquid nozzle PR3 for example, the inserting pin 321441 of the nozzle holder 32144 is made to align with the pin hole 32149 on the casing member 32148 in which the chemical liquid nozzle PR3 is set under the driving of the vertical driving device 32146 and the rotating driving device 32147. Then the driving actuator 32142 drives the nozzle holder 32144 to move forward to make the inserting pin 321441 of the nozzle holder 32144 insert into the pin hole 32149 on the casing member 32148 in which the chemical liquid nozzle PR3 is set. The vertical driving device 32146 drives the supporting shaft 32145 to move upward to make the casing member 32148 in which the chemical liquid nozzle PR3 is set as well as the chemical liquid nozzle PR3 depart from the trough 32140 and be above the trough 32140. The rotating driving device 32147 drives the supporting shaft 32145 to rotate to make the chemical liquid nozzle PR3 be above the substrate. The method for adjusting the chemical liquid nozzle PR3 to align with the center of the substrate is as same as that of coating module 1211 and will not be described herein repeatedly.

The configuration of the edge cleaning apparatuses 3216 and the controller is as same as the edge cleaning apparatuses 1216 and the controller 1215 of the coating module 1211, and will not be described herein repeatedly.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A substrate processing apparatus comprising a chemical liquid processing apparatus configured to perform processing on substrates, wherein the chemical liquid processing apparatus includes:
a first chemical liquid processing part configured to supply a first chemical liquid to the substrates and perform first chemical processing on the substrates;
a second chemical liquid processing part configured to be stacked with the first chemical liquid processing part and to supply a second chemical liquid to the substrates and perform second chemical processing on the substrates;
a heating processing part located opposite the first chemical liquid processing part and the second chemical liquid processing part and configured to perform a heating treatment operation on the substrates before and after the first chemical processing on the substrates or the second chemical processing on the substrates;
a substrate transferring part located between the first and second chemical liquid processing parts and the heating processing part, wherein the substrate transferring part is configured to have:
at least two first robots, at least one second robot and at least one third robot, all of which are arranged in parallel layers, the at least two first robots are configured to transfer the substrates between the first chemical liquid processing part and the heating processing part and the at least one third robot is configured to transfer the substrates between the second chemical liquid processing part and the heating processing part; and
at least one pair of first buffer units located between two adjacent first robots and configured for loading and unloading the substrates therein and therefrom via the at least one second robot.

2. The substrate processing apparatus as claimed in claim 1, wherein the first chemical liquid processing part is configured to perform coating process on the substrates and the second chemical liquid processing part is configured to perform developing process on the substrates.

3. The substrate processing apparatus as claimed in claim 2, wherein the first chemical liquid processing part is located below the second chemical liquid processing part, or the first chemical liquid processing part is located above the second chemical liquid processing part.

4. The substrate processing apparatus as claimed in claim 1, wherein the chemical liquid processing apparatus further comprises fan filter units respectively located above the at least two first robots, the at least one second robot and the at least one third robot.

5. The substrate processing apparatus as claimed in claim 1, wherein at least one of the pair of first buffer units is configured to be capable of ascending and descending.

6. The substrate processing apparatus as claimed in claim 5, wherein the pair of first buffer units is configured to be arranged in one of the following manners: a) the two first buffer units are arranged side by side and parallel to the move direction of the second robot and both of the two first buffer units are configured to be capable of ascending and descending; b) the two first buffer units are arranged to be stacked and both of the two first buffer units are configured to be capable of ascending and descending; c) the two first buffer units are arranged side by side and perpendicular to the move direction of the second robot and both of the two first buffer units are configured to be capable of ascending and descending; d) the two first buffer units are arranged to be stacked and the first buffer unit located above is fixed and the other first buffer unit located below is configured to be capable of ascending and descending.

7. The substrate processing apparatus as claimed in claim 1, further comprising:
a process block in which the chemical liquid processing apparatus is disposed;
a first carrying block configured to carry the substrates which are accommodated in a cassette and are to be processed in the process block to the process block or carry the substrates processed in the process block to the cassette;
a second carrying block configured to carry the substrates processed in the process block or the substrates to be processed in the process block; and
an interface block configured to perform interfacing between the second carrying block and an external apparatus.

8. The substrate processing apparatus as claimed in claim 7, wherein the process block further comprises:
a pair of second buffer units, one of the second buffer units configured to be corresponding to the first carrying block and one of the first robots, and the other of the second buffer units configured to be corresponding to another of the first robots and the second carrying block;
a pair of third buffer units, one of the third buffer units configured to be corresponding to the first carrying block and the second robot, and the other of the third buffer units configured to be corresponding to the second robot and the second carrying block; and
at least a pair of fourth buffer units, one of the fourth buffer units configured to be corresponding to the second carrying block and the third robot, and the other of the fourth buffer units configured to be corresponding to the third robot and the first carrying block.

9. The substrate processing apparatus as claimed in claim 8, wherein the pair of third buffer units is configured to be capable of ascending and descending.

10. The substrate processing apparatus as claimed in claim 8, wherein the fourth buffer units include at least one fourth buffer unit configured to be corresponding to the second carrying block and the third robot and one or more fourth buffer units configured to be corresponding to the third robot and the first carrying block.

11. The substrate processing apparatus as claimed in claim 1, wherein the second robot is arranged below the at least two first robots.

12. The substrate processing apparatus as claimed in claim 1, wherein the second robot is arranged above the at least two first robots.

13. The substrate processing apparatus as claimed in claim 1, wherein two second robots are arranged at both sides of one pair of first buffer units.

14. The substrate processing apparatus as claimed in claim 1, wherein the first chemical liquid processing part includes a plurality of first processing modules, the plurality of first processing modules are arranged into a plurality of columns, and every column has one or more layers.

15. The substrate processing apparatus as claimed in claim 1, wherein the substrate transferring part has a plurality of first robots, and one pair of first buffer units is located between every two adjacent first robots.

16. The substrate processing apparatus as claimed in claim 1, wherein the second chemical liquid processing part includes a plurality of second processing modules, the plurality of second processing modules are arranged into a plurality of columns, and every column has one or more layers.

17. The substrate processing apparatus as claimed in claim 16, wherein the substrate transferring part has a plurality of third robots and every third robot is corresponding to one layer of the second processing modules.

18. The substrate processing apparatus as claimed in claim 1, wherein the heating processing part has a plurality of heating modules, the plurality of heating modules are arranged into a plurality of columns and every column has a plurality of layers, the plurality of heating modules in every column is configured in a wafer cassette form and the interval between the heating modules is adjustable.

19. A chemical liquid processing apparatus comprising at least one nozzle apparatus, at least one processing unit and a controller, wherein the nozzle apparatus comprises:
a supporting arm;
a driving actuator, configured to be positioned on the supporting arm;
a nozzle holder, configured to be connected to the driving actuator and be driven to move by the driving actuator;
at least one nozzle, configured to be fixed with the nozzle holder;
a supporting shaft, configured to be fixed with the supporting arm;
a vertical driving device, configured to be connected to the supporting shaft to drive the supporting shaft to move upwards or downwards;
a rotating driving device, configured to be connected to the supporting shaft to drive the supporting shaft to rotate; and
the controller is configured to be respectively connected to the driving actuator, the vertical driving device and the rotating driving device.

20. The chemical liquid processing apparatus as claimed in claim 19, wherein the driving actuator has a sliding recess, an end of the nozzle holder is disposed in the sliding recess and is configured to move forward or backward in the sliding recess by the driving of the driving actuator.

21. The chemical liquid processing apparatus as claimed in claim 19, wherein the nozzle is a coating nozzle applied for delivering photoresist liquid to substrates positioned in two processing units arranged in the same row, the nozzle apparatus is located at the center between the two processing units.

22. The chemical liquid processing apparatus as claimed in claim 21, wherein the coating nozzle includes:
a solvent nozzle configured to dispense a solvent to the substrates; and
a plurality of chemical liquid nozzles configured to dispense photoresist liquid to the substrates.

23. The chemical liquid processing apparatus as claimed in claim 22, wherein the solvent nozzle and the plurality of chemical liquid nozzles are fixed with the nozzle holder and the solvent nozzle is located at the center among the plurality of chemical liquid nozzles to dispense the solvent to the substrates so that surfaces of the substrates are hydrophilic before the photoresist liquid is dispensed from the plurality of chemical liquid nozzles.

24. The chemical liquid processing apparatus as claimed in claim 22, wherein an end of the nozzle holder protrudes to form an inserting pin, each of the chemical liquid nozzles is configured to be set in a casing member, a side wall of every casing member which is opposite to the end of the nozzle holder sets a pin hole, the inserting pin of the nozzle holder is inserted into the pin hole of every casing member to fetch the corresponding chemical liquid nozzle for dispensing photoresist liquid to the substrates.

25. The chemical liquid processing apparatus as claimed in claim 24, wherein the plurality of casing members is arranged in a trough.

26. The chemical liquid processing apparatus as claimed in claim 24, wherein the solvent nozzle is fixed with the nozzle holder.

27. The chemical liquid processing apparatus as claimed in claim 19, wherein the nozzle is a developing nozzle applied for delivering developing liquid to a substrate positioned in one processing unit.

28. The chemical liquid processing apparatus as claimed in claim 27, wherein the developing nozzle includes:
a plurality of chemical liquid nozzles configured to dispense developing liquid to the substrate; and
a gas nozzle configured to dispense non-reactive gas to the substrate to prevent the developing liquid from being rebounded to the substrate.

29. The chemical liquid processing apparatus as claimed in claim 19, wherein an end of the nozzle holder has at least one hole for mounting the at least one nozzle, the center of the at least one hole and the center of the at least one processing unit are on the same arc.

30. A method for adjusting at least one nozzle to align with a center of a substrate positioned in a processing unit, comprising:
establishing polar coordinates in a controller, wherein the controller is connected to a rotating driving device configured to drive the at least one nozzle to rotate, a vertical driving device configured to drive the at least one nozzle to move upwards or downwards and a driving actuator configured to drive the at least one nozzle to move forwards or backwards;
obtaining a polar point of the at least one nozzle and recording the polar point of the at least one nozzle in the controller, wherein the polar point of the at least one nozzle aligns the center of the substrate in the processing unit;
the controller sending instructs to the rotating driving device and the driving actuator based on the polar point of the at least one nozzle recorded in the controller to make the at least one nozzle reach the polar point so that the at least one nozzle aligns with the center of the substrate in the processing unit.

31. The method as claimed in claim 30, wherein obtaining a polar point of the at least one nozzle further includes:
putting a standard sample in the processing unit and a camera being positioned at the center of the standard sample and connected to the controller;
the rotating driving device driving the at least one nozzle to rotate to make the nozzle align with the camera, if the camera captures the nozzle, record the polar point P(r, θ) of the nozzle in the controller, wherein r is a length L which is the distance from the nozzle to the polar point O, θ is the rotation angle of the nozzle; if the camera doesn't capture the nozzle, the driving actuator drives the nozzle holder to linearly move to make the nozzle move forward or backward until the camera captures the nozzle, record the polar point P(r, θ) of the nozzle in the controller, wherein r is a length L±σ, +σ is the distance that the driving actuator drives the nozzle to move forward, −σ is the distance that the driving actuator drives the nozzle to move backward, θ is the rotation angle of the nozzle.
